(19) United States
(12) Patent Application Publication
(10) Pub. No.: US 2024/0172394 A1
(43) Pub. Date: May 23, 2024

(54) REFRIGERANT CIRCULATION DEVICE AND ELECTRONIC EQUIPMENT

(71) Applicant: Nidec Corporation, Kyoto (JP)

(72) Inventors: Toshihiko TOKESHI, Kyoto (JP); Shinsuke HAMANO, Kyoto (JP); Tomoaki ANDO, Kyoto (JP); Taku MURAKAMI, Kyoto (JP); Hirotaka WATANABE, Kyoto (JP); Naoya NONOMURA, Kyoto (JP)

(21) Appl. No.: 18/512,332

(22) Filed: Nov. 17, 2023

Related U.S. Application Data
(60) Provisional application No. 63/426,106, filed on Nov. 17, 2022.

(30) Foreign Application Priority Data
Aug. 8, 2023 (JP) 2023-129456

(51) Int. Cl. H05K 7/20

(52) U.S. Cl. CPC H05K 7/20272; H05K 7/20781

(57) ABSTRACT

A refrigerant circulation device includes a housing including an opening, a protrusion protruding from the housing, and a pump movable in a first direction in an internal space of the housing through the opening and mounted at a mounting position on one side in the first direction relative to the opening. The pump includes a stopper movable between a first position that does not overlap with the protrusion and a second position that overlaps with the protrusion and is on one side in the first direction relative to the protrusion.

### CROSS-REFERENCE TO RELATED APPLICATIONS

The present application claims priority under 35 U.S.C. § 119 to Japanese Patent Application No. 2023-129456, filed on Aug. 8, 2023, and U.S. Provisional Patent Application No. 63/426,106, filed on Nov. 17, 2022, the entire contents of each are hereby incorporated herein by reference.

### 1. FIELD OF THE INVENTION

The present disclosure relates to a refrigerant circulation device and electronic equipment.

### 2. BACKGROUND

A known refrigerant circulation device cools a cooling target by transmitting, to a circulating refrigerant, heat received from the cooling target. The refrigerant circulation device is also an example of electronic equipment.

The refrigerant circulation device and the electronic equipment are required to have good usability.

### SUMMARY

A refrigerant circulation device according to an example embodiment of the present disclosure includes a first housing including a first opening, a protrusion protruding from the first housing, and a pump that is movable in a first direction in an internal space of the first housing through the first opening and is mounted at a mounting position that is a position of one side in the first direction relative to the first opening in the internal space. The pump includes a first stopper that is movable between a first position that does not overlap with the protrusion in one side of the first direction and a second position that overlaps with the protrusion in one side of the first direction and is on one side in the first direction relative to the protrusion.

A refrigerant circulation device according to another example embodiment of the present disclosure includes a housing including a first opening, a pump mounted in the housing through the first opening, and a display assembly that is provided in a panel to display a screen.

An electronic equipment according to another example embodiment of the present disclosure includes a housing that partitions an internal space, a first circuit board that expands in the internal space, a second circuit board including an edge on which a recess portion is provided, and a mounting assembly attached to the first circuit board and configured to electrically connect the second circuit board to the first circuit board. The mounting assembly includes a guide extending along a first direction intersecting with the first circuit board and including a groove to guide the edge, a projection portion provided in the groove and fitted into the recess portion, and an elastic deformation portion to retract the projection portion from the groove by the edge elastically deforming against the projection portion when the edge is guided in the groove.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a view showing a configuration of a cooling system according to an example embodiment of the present disclosure.

FIG. 2 is an external perspective view of a CDU shown in FIG. 1.

FIG. 3 is an external perspective view of the CDU shown in FIG. 1 as viewed from a direction different from FIG. 2.

FIG. 4 is a transverse cross-sectional view of the CDU taken along line IV-IV shown in FIG. 2.

FIG. 5 is a transverse cross-sectional view of the CDU taken along line V-V shown in FIG. 2.

FIG. 6 is a perspective view showing a pump and a mounting assembly shown in FIG. 3.

FIG. 7 is a perspective view of the pump and the mounting assembly shown in FIG. 3 as viewed from a direction different from FIG. 6.

FIG. 8 is a transverse cross-sectional view of the CDU taken along line VIII-VIII shown in FIG. 2.

FIG. 9 is a schematic diagram showing insertion and removal of each pump into and from the mounting assembly in detail.

FIG. 10 is an enlarged view of an opening shown in FIG. 8.

FIG. 11 is an enlarged perspective view of one pump shown in FIG. 7.

FIG. 12 is a transverse cross-sectional view of the pump taken along line XI-XI shown in FIG. 11.

FIG. 13 is a view showing a state where a first stopper shown in FIG. 11 is at a first position.

FIG. 14 is a view showing a state where the first stopper shown in FIG. 11 is at a second position.

FIG. 15 is a perspective view showing a display assembly in a close state.

FIG. 16 is a perspective view showing the display assembly in an open state.

FIG. 17 is a longitudinal cross-sectional view of the CDU taken along line XVII-XVII shown in FIG. 15.

FIG. 18 is a perspective view showing a detailed configuration of a mounting assembly shown in FIG. 17.

FIG. 19 is a perspective view showing a detailed configuration of a second circuit board shown in FIG. 17.

FIG. 20 is a view showing an example of an image S01 displayed on a touch screen 1132.

FIG. 21 is a perspective view of a pump 17 according to a modification of an example embodiment of the present invention.

FIG. 22 is a longitudinal cross-sectional view of the pump 17 taken along line XXII-XXII of FIG. 21.

### DETAILED DESCRIPTION

Hereinafter, example embodiments of the present disclosure will be described with reference to the drawings. In the drawings, the same or corresponding elements are denoted by the same reference signs, and the description will not be repeated.

In each example embodiment, a Z direction, an X direction, and a Y direction intersecting one another are appropriately used for easy understanding. In each example embodiment, the term “intersect” includes lines, planes, or a line and a plane intersecting each other at a right angle. The term “intersect” also includes lines, planes, or a line and a plane intersecting each other at a non-right angle in a range to an extent of a slight difference. The slight difference includes a tolerance and an error.

Hereinafter, the positions in the Z direction, the X direction, and the Y direction may be referred to as a “Z position”, an “X position”, and a “Y position”, respectively. Dimensions in the Z direction, the X direction, and the Y direction may be referred to as “Z dimension”, “X dimension”, and “Y dimension”, respectively.

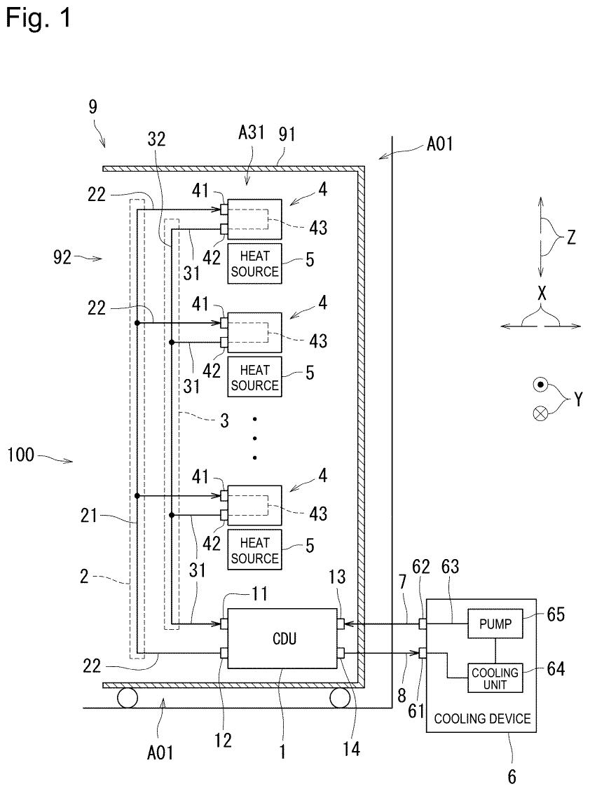

FIG. 1 is a schematic diagram showing the configuration of a cooling system 100 according to a first example embodiment. As shown in FIG. 1, the cooling system 100 includes, as elements, a CDU 1, a distribution manifold 2, a collection manifold 3, at least one cold plate 4, a cooling device 6, and flow paths 7 and 8. With these elements, the cooling system 100 cools at least one heat source 5 installed in a space A01.

When the cooling system 100 includes one cold plate 4, the cooling system 100 needs not include the distribution manifold 2 and the collection manifold 3.

Among the elements of the cooling system 100, the CDU 1, the distribution manifold 2, the collection manifold 3, and a plurality of the cold plates 4 are installed in the space A01. The space A01 is, for example, a server room.

The space A01 is provided with a rack 9. A plurality of the heat sources 5 are accommodated in the rack 9. The plurality of heat sources 5 are accommodated in the rack 9 so as to be aligned in a specific direction. The specific direction is, for example, the Z direction or the Y direction.

Each heat source 5 is typically an electronic component or electronic equipment. The electronic component is a component constituting electronic equipment, and includes, for example, a central processing unit (so-called CPU), an electrolytic capacitor, a power semiconductor module, or a printed circuit board. The electronic component operates by power supply and generates heat. The electronic equipment is a rack mounted server or a blade server. The electronic equipment may also be a projector, a personal computer, or a display.

The CDU 1 is an example of the “refrigerant circulation device” of the present disclosure. The CDU 1 can be distributed in the marketplace as the cooling system 100 (excluding the cooling device 6 and the flow paths 7 and 8). However, the present disclosure is not limited to this, and the CDU 1 may be distributed alone in the market. In the example embodiment, the CDU 1 is accommodated, for example, in the rack 9 in use. However, the present disclosure is not limited to this, and the CDU 1 may be installed outside the rack 9 in use.

The CDU 1 includes a primary inflow port 11, a primary outflow port 12, a secondary inflow port 13, and a secondary outflow port 14. A high-temperature primary refrigerant flows into the primary inflow port 11 from the collection manifold 3. A low-temperature secondary refrigerant flows into the secondary inflow port 13 through the flow path 7. The CDU 1 performs heat exchange between the primary refrigerant (high temperature) flowing into the CDU 1 from the primary inflow port 11 and the secondary refrigerant (low temperature) flowing into the CDU 1 from the secondary inflow port 13. Due to this, in the CDU 1, heat energy of the primary refrigerant moves to the secondary refrigerant. That is, the temperature of the primary refrigerant decreases as compared with that when flowing into the CDU 1 by heat exchange. The CDU 1 pumps the primary refrigerant having reached low temperature from the primary outflow port 12 toward the distribution manifold 2. The secondary refrigerant having reached high temperature is sent out from the secondary outflow port 14 to the flow path 8.

The primary refrigerant is, for example, a coolant. Examples of the coolant include antifreeze liquid or pure water. A typical example of antifreeze liquid is an ethylene glycol aqueous solution or a propylene glycol aqueous solution. The secondary refrigerant is a refrigerant of the same type as or a different type from the primary refrigerant. At least one of the primary refrigerant and the secondary refrigerant may be a gas refrigerant.

The distribution manifold 2 has a common flow path 21 and a plurality of individual flow paths 22. FIG. 1 shows only three individual flow paths 22 for the purpose of easy understanding. The primary refrigerant can be distributed through the common flow path 21 and each of the plurality of individual flow paths 22. One end of each of the individual flow paths 22 is connected to the common flow path 21 so that the primary refrigerant can be distributed. The other end of one of the plurality of individual flow paths 22 is connected to the primary outflow port 12 of the CDU 1 and used as an inflow port of the primary refrigerant in the distribution manifold 2. The other ends of the remaining individual flow paths 22 are used as outflow ports for the primary refrigerant in the distribution manifold 2 and are individually connected to an inflow port 41 of the cold plate 4. Therefore, the primary refrigerant (low temperature) flowing into the inflow port of the distribution manifold 2 is distributed from one of the individual flow paths 22 to the common flow path 21, is branched by the remaining individual flow paths 22, and then flows out from each outflow port of the distribution manifold 2.

Each cold plate 4 is in thermal contact with at least one heat source 5. The primary refrigerant (low temperature) flows inside each cold plate 4. In detail, each cold plate 4 is arranged in direct thermal contact with the heat source 5. Each cold plate 4 may be arranged in thermal contact with the heat source 5, for example via a thermally conductive sheet (not shown). That is, the term “thermal contact” includes the meaning of “direct thermal contact” and the meaning of “indirect thermal contact”.

Each cold plate 4 has an inflow port 41 for the primary refrigerant, an outflow port 42, and an internal flow path 43. The internal flow path 43 connects the inflow port 41 and the outflow port 42 so that the primary refrigerant can be distributed. The primary refrigerant (low temperature) flows into the inflow port 41 from the individual flow path 22 connected to the inflow port 41. The primary refrigerant is distributed in the internal flow path 43 toward the outflow port 42. Therefore, the heat energy generated at the heat source 5 moves to the primary refrigerant flowing through the internal flow path 43 of the cold plate 4 in thermal contact with the heat source 5. As a result, the heat source 5 is cooled, and the temperature of the primary refrigerant rises. The primary refrigerant (high temperature) flows out from the outflow port 42 to an individual flow path 31 of the collection manifold 3.

The collection manifold 3 has a plurality of the individual flow paths 31 and a common flow path 32. FIG. 1 shows three individual flow paths 31 for the purpose of easy understanding. The primary refrigerant can be distributed through each of the plurality of individual flow paths 31 and the common flow path 32. One end of each of the individual flow paths 31 is connected to the common flow path 32 so that the primary refrigerant can be distributed. The other end of one of all the individual flow paths 31 is used as an outflow port of the primary refrigerant in the collection manifold 3 and is connected to the primary inflow port 11 of the CDU 1. The other ends of the remaining individual flow paths 31 are individually connected to the outflow port 42 of the cold plate 4 as inflow ports of the primary refrigerant in the collection manifold 3. Therefore, the primary refrigerant flowing from the cold plate 4 into each inflow port in the individual flow path 31 joins in the common flow path 32, and flows out from the outflow port of the individual flow path 31 to the primary inflow port 11 of the CDU 1. Therefore, the primary refrigerant circulates through the CDU 1, the distribution manifold 2, the cold plate 4, and the collection manifold 3 in this order.

The cooling device 6 is installed outside the space A01, for example. The cooling device 6 may be installed any of indoors and outdoors. The cooling device 6 is, for example, a chiller or a cooling tower. The cooling device 6 includes an inflow port 61 for the secondary refrigerant, an outflow port 62, an internal flow path 63, a cooling unit 64, and a pump 65. The internal flow path 63 connects the inflow port 61 and the outflow port 62 so that the secondary refrigerant can be distributed. The cooling unit 64 and the pump 65 are inserted on the internal flow path 63.

The secondary refrigerant flowing into the inflow port 61 flows into the cooling unit 64 through the flow path. The cooling unit 64 cools the secondary refrigerant flowing into the cooling unit 64. The cooling system in the cooling unit 64 may be any of an air cooling system and a water cooling system. The secondary refrigerant flowing out of the cooling unit 64 flows into the pump 65 through the flow path. The pump 65 pumps, toward the outflow port 62, the secondary refrigerant flowing into the pump 65. In FIG. 1, the pump 65 is positioned between the cooling unit 64 and the outflow port 62 in the flow path of the secondary refrigerant. However, the present disclosure is not limited to this, and the pump 65 may be positioned between the outflow port 62 and the cooling unit 64 in the flow path of the secondary refrigerant.

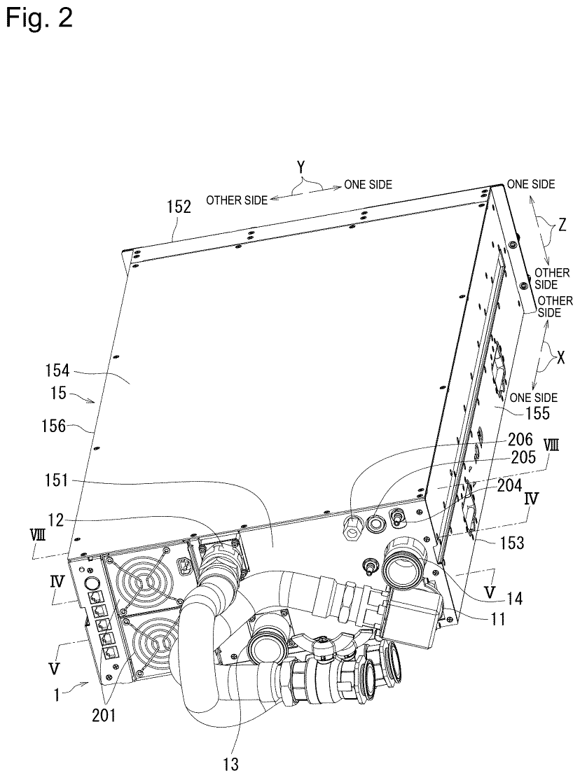

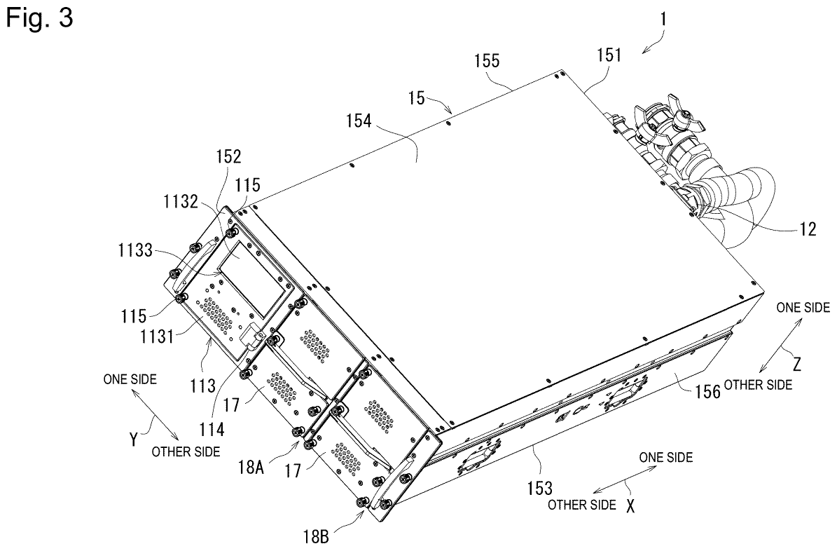

FIG. 2 is an external perspective view of the CDU 1 shown in FIG. 1. FIG. 3 is an external perspective view of the CDU 1 shown in FIG. 1 as viewed from a different direction from FIG. 2.

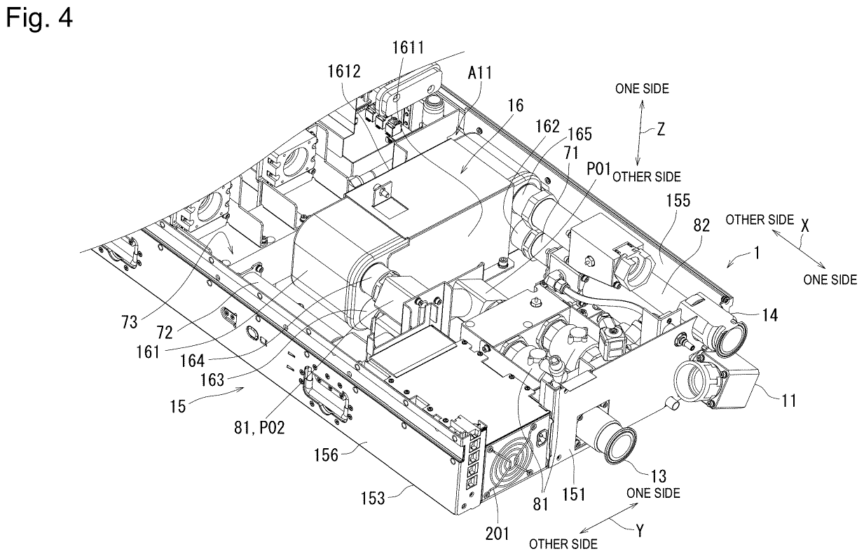

As shown in FIGS. 2 and 3, the CDU 1 includes a housing 15. The outer shape of the housing 15 is, for example, a substantially rectangular cuboid shape, and is relatively thin in the Z direction and relatively long in the X direction. The housing 15 includes panels 151 to 156. The panels 151 to 156 define the outer shape of the housing 15. The panels 151 to 156 partition an internal space A11 (see FIG. 4) of the housing 15 from the outside.

The panels 151 and 152 are separated from each other in the X direction. In the example embodiment, the panel 151 is positioned on one side in the X direction with respect to the panel 152. Each of the panels 151 and 152 extends in both the Z direction and the Y direction.

The panels 153 and 154 are separated from each other in the Z direction. In the example embodiment, the panel 154 is positioned on one side in the Z direction with respect to the panel 153. Each of the panels 153 and 154 extends in both the X direction and the Y direction.

The panels 155 and 156 are separated from each other in the Y direction. In the example embodiment, the panel 155 is positioned on one side in the Y direction with respect to the panel 156. Each of the panels 155 and 156 extends in both the Z direction and the X direction.

As shown in FIG. 2, the housing 15 has, as four ports on the panel 151, the primary inflow port 11, the primary outflow port 12, the secondary inflow port 13, and the secondary outflow port 14. Each of the four ports is positioned to the right relative to a power supply unit 201 toward the panel 151. Each of the four ports protrudes from the panel 151 in one side in the X direction.

The primary inflow port 11 is positioned at the lower right corner of the panel 151 as viewed toward the panel 151, for example. In other words, the primary inflow port 11 is positioned near the other end in the Z direction and near one end in the Y direction of the panel 151.

The secondary inflow port 13 is positioned on the left of the primary inflow port 11 as viewed toward the panel 151, for example. In other words, the secondary inflow port 13 is positioned on the other side in the Y direction with respect to the primary inflow port 11.

The primary outflow port 12 is positioned on the obliquely upward left of the secondary inflow port 13 as viewed toward the panel 151, for example. In other words, the primary outflow port 12 is positioned on the other side in the Y direction and on one side in the Z direction with respect to the secondary inflow port 13.

The secondary outflow port 14 is positioned above the primary inflow port 11 as viewed toward the panel 151, for example. In other words, the secondary outflow port 14 is positioned on one side in the Z direction with respect to the primary inflow port 11.

FIG. 4 is a transverse cross-sectional view of the CDU 1 taken along line IV-IV shown in FIG. 2. FIG. 4 omits illustration of the panel 154 for easy understanding. As shown in FIG. 4, the CDU 1 includes individual pipes 71 and 81. The individual pipes 71 and 81 are installed in the internal space A11.

The individual pipe 71 defines a part of the primary flow path. The primary flow path is a flow path for the primary refrigerant in the CDU 1. The individual pipe 71 connects the primary inflow port 11 and a primary pipe 162 of a heat exchanger 16 of plate type so that the primary refrigerant can be distributed therebetween. In the example embodiment, the individual pipe 71 extends substantially straight along the X direction. Therefore, the distance between the primary inflow port 11 and the primary pipe 162 is relatively shortened.

The individual pipe 81 defines a part of the secondary flow path. The secondary flow path is a flow path for the secondary refrigerant in the CDU 1. The individual pipe 81 connects the secondary inflow port 13 and a secondary pipe 164 of the heat exchanger 16 so that the secondary refrigerant can be distributed therebetween. In the example embodiment, the individual pipe 81 extends from the secondary inflow port 13 to the other side in the X direction along the panel 153 and is bent at a position P01 on one side in the X direction relative to the heat exchanger 16. The individual pipe 81 extends from the position P01 to one side in the Z direction and the other side in the Y direction, and reaches a position P02 on the other side in the Z direction relative to the panel 154 (see FIG. 3). The individual pipe 81 extends from the position P02 to the other side in the X direction and reaches the secondary pipe 164 of the heat exchanger 16.

As shown in FIG. 4, the CDU 1 further includes the heat exchanger 16 of plate type. The heat exchanger 16 has a housing 161 having a substantially rectangular cuboid shape, for example. The housing 161 is relatively long in the Y direction and relatively thin in the Z direction. The housing 161 is positioned substantially at the center of the panel 151 and 152 (see FIG. 3) in the X direction. In the Y direction, the housing 161 is positioned closer to the panel 155 than the panel 156. In detail, the housing 161 is close to the panel 155 via a slight gap. In the Z direction, the housing 161 is positioned closer to the panel 153 than the panel 154 (see FIG. 3). More in detail, the housing 161 is close to the panel 153 via a slight gap. That is, the housing 161 is positioned away on the other side in the Z direction from the panel 154.

The heat exchanger 16 includes a multitude of heat transfer plates, primary pipes 162 and 163, and secondary pipes 164 and 165 in the housing 161. The heat transfer plates are arrayed in the X direction at no intervals in the X direction in the housing 161. It is also possible to array the heat transfer plates in the X direction at slight intervals in the X direction. Each of the heat transfer plates has a rectangular shape extending in each of the Z direction and the Y direction.

The primary pipes 162 and 163 and the secondary pipes 164 and 165 each penetrate both end faces 1611 and 1612 of the housing 161. The end faces 1611 and 1612 are positioned at one end in the X direction and the other end in the X direction in the housing 161, respectively. The primary pipes 162 and 163 and the secondary pipes 164 and 165 each also penetrate the heat transfer plates positioned between the both end faces 1611 and 1612. In the example embodiment, the primary pipes 162 and 163 and the secondary pipes 164 and 165 each extend substantially straight along the X direction.

The primary pipe 162 is positioned near one end in the Y direction and the other end in the Z direction in the housing 161. The primary pipe 163 is positioned near the other end in the Y direction and the other end in the Z direction in the housing 161. The secondary pipe 164 is positioned near the other end in the Y direction and the one end in the Z direction in the housing 161. The secondary pipe 165 is positioned near one end in the Y direction and one end in the Z direction in the housing 161.

The other end in the X direction of each of the primary pipes 162 and 163 and the secondary pipes 164 and 165 is fully closed. The primary pipe 162 is connected to the other end in the X direction of the individual pipe 71 so that the primary refrigerant can be distributed. The secondary pipe 164 is connected to the other end in the X direction of the individual pipe 81 so that the secondary refrigerant can be distributed.

The primary refrigerant is distributed from the primary pipe 162 to the primary pipe 163 through the multitude of heat transfer plates. The secondary refrigerant is distributed from the secondary pipe 164 to the secondary pipe 165 through the multitude of heat transfer plates. In the multitude of heat transfer plates, the primary refrigerant having a high temperature and the secondary refrigerant having a low temperature are distributed in a physically separated state. On the other hand, the multitude of heat transfer plates are made of a material having a relatively small heat transfer resistance. Therefore, in the multitude of heat transfer plates, heat exchange is performed between the primary refrigerant (high temperature) and the secondary refrigerant (low temperature), and as a result, heat energy of the primary refrigerant moves to the secondary refrigerant. That is, the temperature of the primary refrigerant distributed in the primary pipe 163 becomes low as compared with that when distributed in the primary pipe 162.

As shown in FIG. 4, the CDU 1 further includes an individual pipe 82. The individual pipe 82 is installed in the internal space A11. The individual pipe 82 defines a part of the secondary flow path. The individual pipe 82 connects the secondary pipe 165 and the secondary outflow port 14 so that the secondary refrigerant can be distributed therebetween. In the example embodiment, the individual pipe 82 extends substantially straight along the X direction. Therefore, the distance between the secondary pipe 165 and the secondary outflow port 14 is shortened.

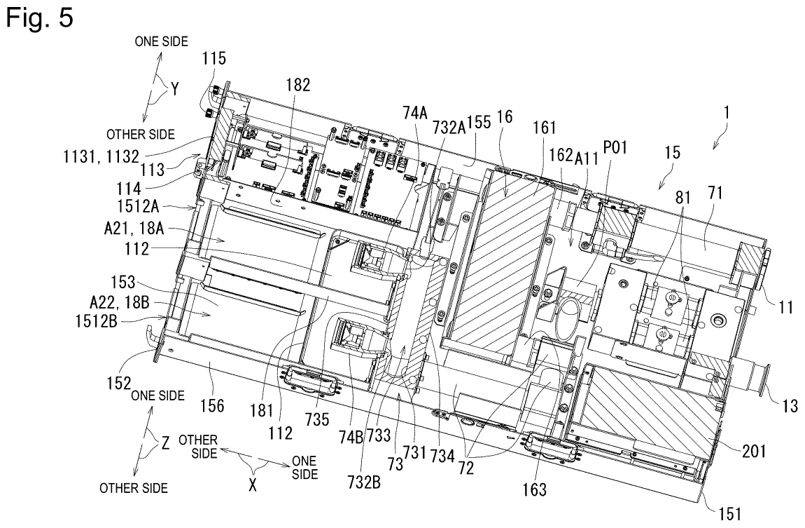

FIG. 5 is a transverse cross-sectional view of the CDU 1 taken along line V-V shown in FIG. 2. As shown in FIG. 5, the CDU 1 further includes a common pipe 72, a branch pipe 73, and two sockets 74A and 74B. The common pipe 72, the branch pipe 73, and two sockets 74A and 74B are installed in the internal space A11. The common pipe 72, the branch pipe 73, and two sockets 74A and 74B define a part of the primary flow path.

The common pipe 72 connects the primary pipe 163 and the branch pipe 73 so that the primary refrigerant can be distributed therebetween. In the example embodiment, the common pipe 72 extends straight from the primary pipe 163 in one side in the X direction along the panel 153, makes a U-turn in the middle, passes between the heat exchanger 16 and the panel 156, and reaches an inflow port 731 of the branch pipe 73.

The branch pipe 73 has a substantially rectangular cuboid shape long in the Y direction. The arrangement of the branch pipe 73 is not particularly limited, but is as follows in the example embodiment. In the X direction, the branch pipe 73 is positioned close to the panel 152 relative to substantially the center of the panels 151 and 152. In the Y direction, the branch pipe 73 is positioned closer to the panel 156 than the panel 155. In detail, the branch pipe 73 is close to the panel 156 via a slight gap. In the Z direction, the branch pipe 73 is positioned closer to the panel 153 than the panel 154 (see FIG. 3). More in detail, the branch pipe 73 is close to the panel 153 via a slight gap. That is, the branch pipe 73 is positioned away in one side in the Z direction from the panel 154.

The branch pipe 73 includes the inflow port 731, two outflow ports 732A and 732B, and an internal flow path 733.

The inflow port 731 is formed on a face 734 facing one side in the X direction in the branch pipe 73. The inflow port 731 penetrates in the X direction from the face 734 to the internal flow path 733. The inflow port 731 is formed at substantially the same position as the common pipe 72 in the Z direction. The inflow port 731 is formed at a position between the heat exchanger 16 and the panel 156 in the Y direction.

The outflow ports 732A and 732B are formed on a face 735 facing the other side in the X direction of the branch pipe 73. On the face 735, the outflow ports 732A and 732B are formed at positions different from each other in the Y direction. In detail, the outflow port 732A is positioned on one side in the Y direction with respect to the outflow port 732B. The outflow ports 732A and 732B are formed at the same position in each of the Z direction and the X direction. The outflow ports 732A and 732B penetrate in the X direction from the face 735 to the internal flow path 733.

The internal flow path 733 connects the inflow port 731 and the outflow ports 732A and 732B so that the primary refrigerant can be distributed. Therefore, the branch pipe 73 guides and bifurcates the primary refrigerant flowing into the inflow port 731 to the outflow ports 732A and 732B through the internal flow path 733.

The sockets 74A and 74B are connected to the outflow ports 732A and 732B so that the primary refrigerant can be distributed therethrough. In the example embodiment, the sockets 74A and 74B protrude from the outflow ports 732A and 732B to the other side in the X direction. The sockets 74A and 74B are paired with suction ports 171 (plugs) of the pump 17 described later, and constitute a coupler together with the suction ports 171.

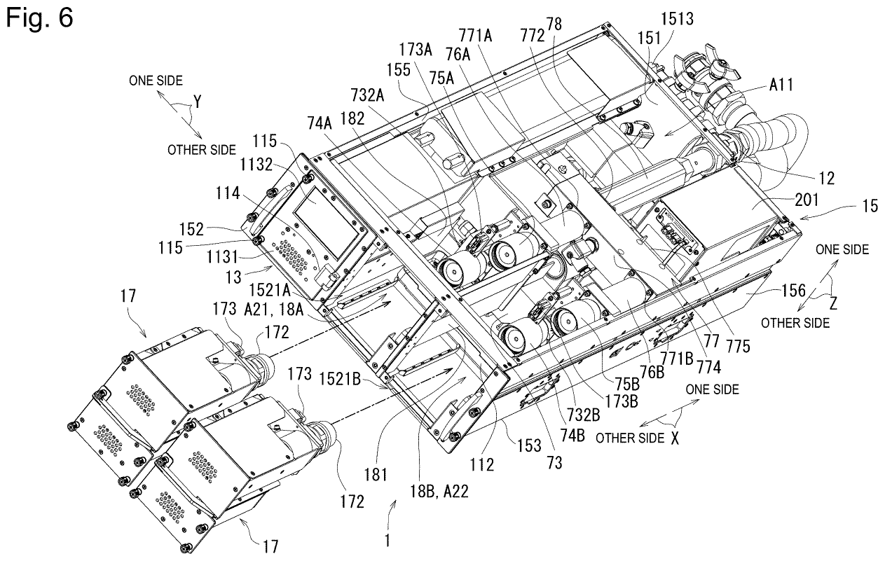

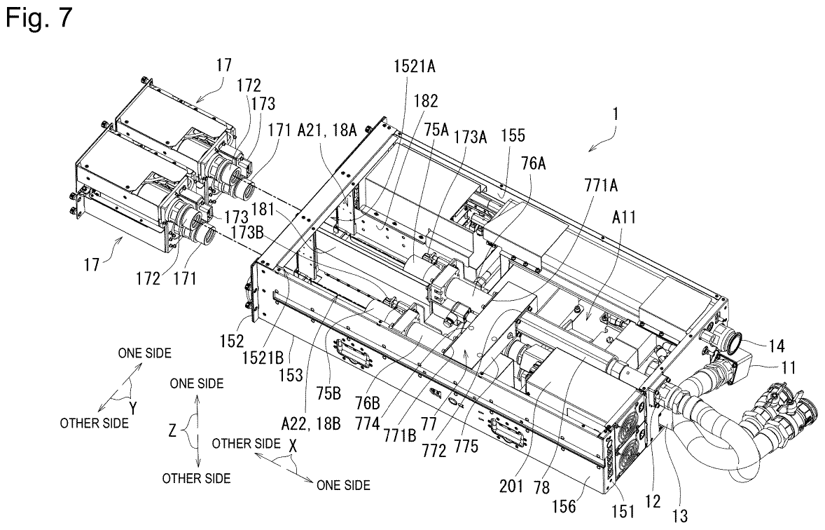

FIG. 6 is a perspective view showing the pump 17 and mounting assemblies 18A and 18B shown in FIG. 3. FIG. 7 is a perspective view of the pump 17 and the mounting assemblies 18A and 18B shown in FIG. 3 as viewed from a direction different from that in FIG. 6.

As shown in FIGS. 6 and 7, the CDU 1 further includes the pump 17. In the example embodiment, the number of the pumps 17 is two. The number of the pumps 17 may be at least one. The two pumps 17 are preferably manufactured in accordance with the same specifications.

Each pump 17 is detachably mounted to the mounting assemblies 18A and 18B in an insertable and removable manner. Each pump 17 can pump the primary refrigerant in the primary flow path by operating in a state of being mounted to the mounting assemblies 18A and 18B (hereinafter, described as a “mounted state”).

Each pump 17 includes the suction port 171 and a discharge port 172 for the primary refrigerant, and a connector 173. Each pump 17 includes an internal flow path, a pump rotor, and a pump motor (none shown).

The suction ports 171 and the discharge ports 172 are plugs. The suction ports 171 (plugs) are paired with the respective sockets 74A and 74B, and constitutes the coupler together with the sockets 74A and 74B. Valves provided in the sockets 74A and 74B are opened in response to mounting of the suction ports 171 to the sockets 74A and 74B. On the other hand, the valves of the sockets 74A and 74B are closed in response to removal of the suction ports 171 from the sockets 74A and 74B.

The discharge ports 172 (plugs) are paired with respective sockets 75A and 75B described later, and constitutes the coupler together with the sockets 75A and 75B. The discharge ports 172 have the same specifications as those of the suction ports 171. The sockets 75A and 75B have the same specifications as those of the sockets 74A and 74B.

In each pump 17, the internal flow path connects the suction port 171 and the discharge port 172 so that the primary refrigerant can be distributed therethrough. That is, the internal flow path is a part of the primary flow path. Each pump rotor is arranged on the internal flow path. Each pump motor generates power under the control of a control unit 202, and applies the generated power to the pump rotor of the same pump 17.

When each pump 17 is in the mounted state, the suction port 171 is connected to the socket 74A or the socket 74B so that the primary refrigerant can be distributed, and the discharge port 172 is connected to the socket 75A or the socket 75B so that the primary refrigerant can be distributed.

In each pump 17, by rotating by power from the pump motor, the pump rotor applies pressure to the primary refrigerant distributed in the internal flow path. As a result, the primary refrigerant in the suction port 171 is sucked into the internal flow path of the pump 17. The sucked refrigerant is pumped by the pump rotor of the pump 17, and is discharged from the discharge port 172 to the sockets 75A and 75B.

The type of each pump 17 is not particularly limited. That is, as the pump 17, for example, a centrifugal pump, a propeller pump, a viscous pump, or a rotary pump can be employed. When the pump 17 is a centrifugal pump, a propeller pump, a viscous pump, or a gear pump, the pump rotor is a vane wheel (impeller). When the pump 17 is a screw pump, the pump rotor is a screw.

Details of the connector 173 will be described later.

As shown in FIGS. 5 to 7, two openings 1521A and 1521B are formed at positions different from each other in the panel 152. That is, the housing 15 has the openings 1521A and 1521B. The housing 15 is an example of the “first housing” of the present disclosure, and the openings 1521A and 1521B are examples of the “first opening” of the present disclosure. The number of openings may be other than two. The openings 1521A and 1521B have a substantially rectangular shape in plan view from the X direction. The openings 1521A and 1521B are opened toward the other side in the X direction and are continuous with the internal space A11. The opening 1521A is positioned on one side in the Y direction with respect to the opening 1521B. The opening 1521A has a shape of the opening 1521B translated in one side of the Y direction.

The internal space A11 is provided with partition walls 181 and 182. The partition walls 181 and 182 extend in both the Z direction and the X direction. In particular, the partition wall 181 extends in one side in the X direction from an intermediate position between the openings 1521A and 1521B and reaches an intermediate position between tip ends of individual pipes 73A and 73B. The partition wall 182 extends in one side in the X direction from a position slightly on one side in the Y direction relative to the opening 1521A and reaches a position slightly on one side in the Y direction from the tip end of the individual pipe 73A.

The CDU 1 further includes the mounting assemblies 18A and 18B. The mounting assembly 18A includes the partition walls 181 and 182 and parts of the panels 153 and 154, and partitions, in the internal space A11, a space (hereinafter, referred to as an “accommodation space”) A21 where one pump 17 is accommodated. The mounting assembly 18B includes the partition wall 181 and parts of the panels 153, 154, and 156, and partitions, in the internal space A11, an accommodation space A22 different from the accommodation space A21. The mounting assemblies 18A and 18B guide movement in the X direction of the pump 17 inserted and removed through the openings 1521A and 1521B, respectively.

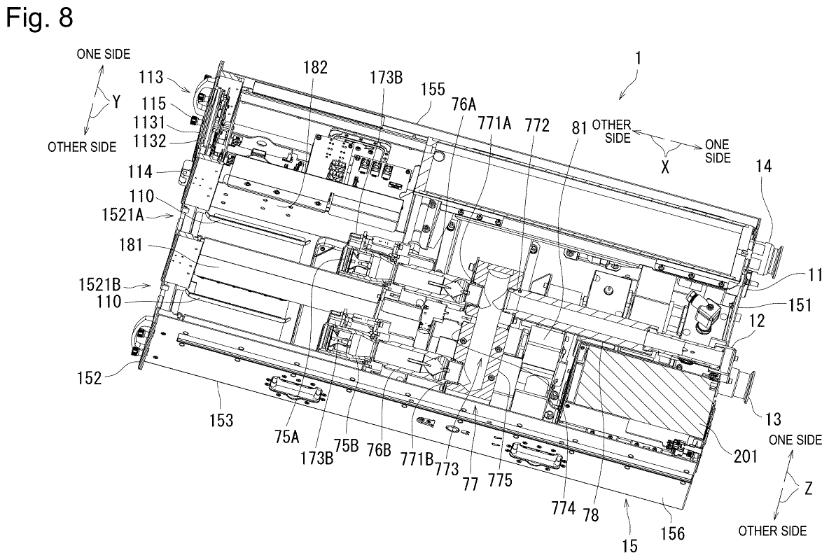

FIG. 8 is a transverse cross-sectional view of the CDU 1 taken along line VIII-VIII shown in FIG. 2. As shown in FIG. 8, the CDU 1 includes, in the housing 15, the two sockets 75A and 75B, individual flow paths 76A and 76B, a junction pipe 77, and a common pipe 78 as other parts of the primary flow path. The sockets 75A and 75B, the individual flow paths 76A and 76B, the junction pipe 77, and the common pipe 78 are installed in the internal space A11 and define another part of the primary flow path.

The junction pipe 77 has a substantially rectangular cuboid shape relatively long in the Y direction. The arrangement of the junction pipe 77 is not particularly limited, but is as follows in the example embodiment. First, in the X direction, the junction pipe 77 is positioned close to the panel 151 relative to substantially the center of the panels 151 and 152. In the Y direction, the junction pipe 77 is positioned closer to the panel 156 than the panel 155. In detail, the junction pipe 77 is close to the panel 156 via a slight gap. In the Z direction, the junction pipe 77 is positioned closer to the panel 154 (see FIG. 3) than the panel 153. The junction pipe 77 is positioned on one side in the Z direction relative to the common pipe 72 and the heat exchanger 16.

The junction pipe 77 has two inflow ports 771A and 771B, one outflow port 772, and an internal flow path 773.

The inflow ports 771A and 771B are formed on a face 774 facing the other side in the X direction of the junction pipe 77. On the face 774, the inflow ports 771A and 771B are formed at positions different from each other in the Y direction. In detail, the inflow port 771A is positioned on one side in the Y direction with respect to the inflow port 771B. The inflow ports 771A and 771B are formed at the same position in each of the Z direction and the X direction. The inflow ports 771A and 771B penetrate in the X direction from the face 774 to the internal flow path 773.

The individual flow path 76A connects the socket 75A and the inflow port 771A so that the primary refrigerant can be distributed therebetween. The individual flow path 76B connects the socket 75B and the inflow port 771B so that the primary refrigerant can be distributed therebetween. Therefore, the sockets 75A and 75B are positioned on the obliquely upward right of the sockets 74A and 74B as viewed from the other side in the X direction (see FIG. 6). With such arrangement, the housing 15 is downsized in the Z direction and the Y direction. In the example embodiment, the individual flow paths 76A and 76B extend substantially straight in the X direction.

The outflow port 772 is formed on a face 775 facing one side in the X direction in the junction pipe 77. In detail, the outflow port 772 is formed at a position close to one side in the Y direction on the face 775. The outflow port 772 penetrates on the other side in the X direction from the face 775 to an internal flow path 763. Therefore, in the junction pipe 77, the primary refrigerant flows into the inflow ports 771A and 771B through the sockets 75A and 75B, respectively. The junction pipe 77 causes the primary refrigerant flowing into the inflow ports 771A and 771B to join by the internal flow path 773 and guides it to the outflow port 772.

The common pipe 78 connects the outflow port 772 and the primary outflow port 12 so that the primary refrigerant can be distributed therebetween. In the example embodiment, the common pipe 78 extends straight from the outflow port 772 along the panel 154 (see FIG. 3) in the X direction and reaches the primary outflow port 12. Therefore, the distance between the outflow port 772 and the primary outflow port 12 is relatively shortened.

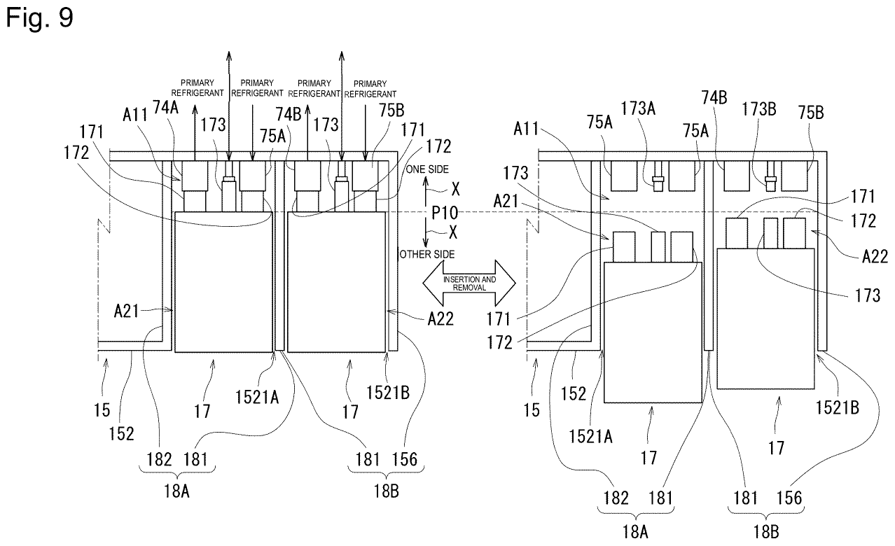

FIG. 9 is a schematic diagram showing insertion and removal of each pump 17 into and from the mounting assemblies 18A and 18B in detail. As shown in FIG. 9, each pump 17 is movable in the X direction in the accommodation spaces A21 and A22 mentioned above through any of the openings 1521A and 1521B.

In detail, at the time of insertion, the pump 17 is moved in one side in the X direction in the internal space A10 while being guided by the mounting assemblies 18A and 18B through any of the openings 1521A and 1521B by an external force applied by a human. The pump 17 is mounted to the mounting assemblies 18A and 18B at a mounting position P10 defined in advance in the accommodation spaces A21 and A22. In other words, each pump 17 cannot move in one side in the X direction beyond each mounting position P10. A state where each pump 17 is correctly positioned at the mounting position P10 corresponds to the mounted state mentioned above. The mounting position P10 is a position on one side in the X direction relative to any of the openings 1521A and 1521B.

The sockets 74A and 75A and a connector 173A are positioned near one end in the X direction in the mounting assembly 18A. The sockets 74B and 75B and a connector 173B are positioned near one end in the X direction in the mounting assembly 18B.

When the pump 17 is in the mounted state in the mounting assembly 18A, the suction port 171 and the discharge port 172 (i.e., the plugs) are connected to the socket 74A and socket 75A, respectively, and the connector 173A is connected to the connector 173. As a result, the primary refrigerant can be distributed from the socket 74A to the suction port 171, and the primary refrigerant can be distributed from the discharge port 172 to the socket 75A. Also when the pump 17 is in the mounted state in the mounting assembly 18B, each unit is connected similarly to the case where the pump 17 is in the mounted state in the mounting assembly 18A. In order to correctly operate the CDU 1, each pump 17 is fixed to the housing 15 by a fixing structure of the pump 17 described later.

On the other hand, when the pump 17 is removed, first, the fixing of the pump 17 to the housing 15 is released. Thereafter, an external force to the other side in the X direction is applied to the pump 17 by the human. Due to this, the pump 17 is moved from the mounting position P10 to the other side in the X direction. In that process, the suction port 171 and the discharge port 172 (i.e., the plugs) of the pump 17 are removed from a socket 74 and a socket 75, respectively. Thereafter, the pump 17 is removed through any of the openings 1521A and 1521B while being guided by the mounting assemblies 18A and 18B.

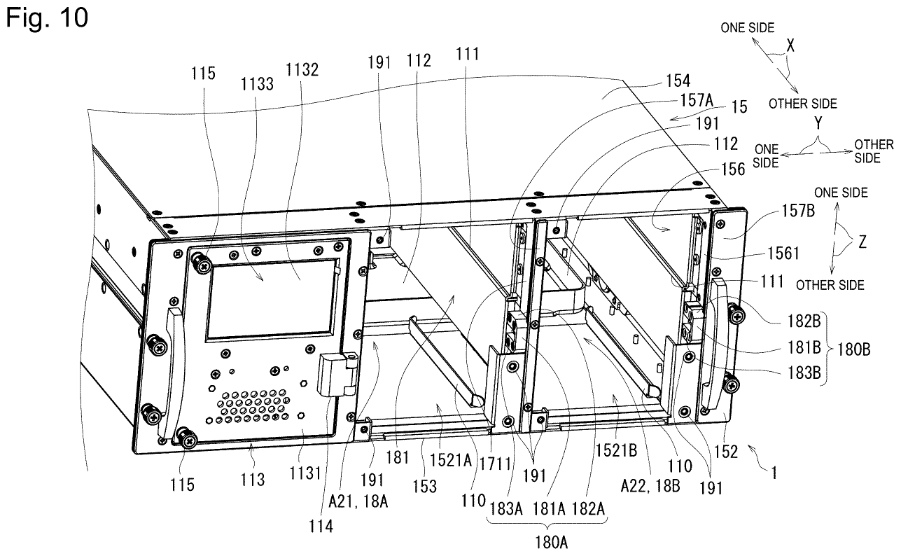

FIG. 10 is an enlarged view of the openings 1521A and 1521B shown in FIG. 8. As shown in FIG. 10, the CDU 1 includes protrusion portions 180A and 180B as parts of the fixing structure of the pump 17 for each of the openings 1521A and 1521B.

The protrusion portion 180B includes a protrusion 181B and regulation portions 182B and 183B. That is, the CDU 1 includes the protrusion 181B.

The protrusion portion 180B is attached to a face 1561 facing one side in the Y direction in the panel 156 by a fixing tool such as a screw. The arrangement of the protrusion portion 180B is not particularly limited, but is as follows in the example embodiment.

In detail, the protrusion portion 180B is positioned substantially at the other end in the X direction on the face 1561. In the Z direction, the protrusion portion 180B is positioned substantially at the center between one end in the Z direction and the other end in the Z direction on the face 1561. At such position, the protrusion portion 180B protrudes by a first protrusion amount toward the inside of the accommodation space A22 (i.e., in one direction in the Y direction) relative to the face 1561. The first protrusion amount is determined to such an extent that the pump 17 moving in the accommodation space A22 and the protrusion portion 180B do not interfere with each other.

The protrusion 181B protrudes from the housing 15. In the example embodiment, the protrusion 181B protrudes inward of the opening 1521B relative to an edge 157B of the opening 1521B in the housing 15. However, the present disclosure is not limited to this, and the protrusion 181B may protrude in any direction outside the opening 1521B relative to the edge 157B of the opening 1521B in the housing 15.

The edge 157B is a part positioned on the other side in the Y direction in the peripheral edge of the opening 1521B in the housing 15. The protrusion 181B has a plate shape thin in the X direction and expanding along the opening 1521B. That is, the protrusion 181B extends in both the Z direction and the Y direction. The protrusion 181B has, for example, a substantially rectangular shape in plan view from the X direction.

The regulation portions 182B and 183B extend along one side in the X direction from one end in the Z direction and the other end in the Z direction of the protrusion 181B. The regulation portions 182B and 183B are separated from each other in the Z direction.

A protrusion 181A includes the protrusion 181A and regulation portions 182A and 183A. That is, the CDU 1 includes the protrusion 181A. The protrusion 181A and the regulation portions 182A and 183A are different from the protrusion 181B and the regulation portions 182B and 183B in that the protrusion 181A and the regulation portions 182A and 183A have shapes of the protrusion 181B and the regulation portions 182B and 183B translated in one side of the Y direction. Therefore, details of the protrusion 181A and the regulation portions 182A and 183A will be omitted.

The CDU 1 includes a base portion where at least one screw hole 191 is formed at each peripheral edge of the openings 1521A and 1521B in the panel 152. In the example embodiment, the CDU 1 includes one base portion at each of three locations on each peripheral edge of the panel 152.

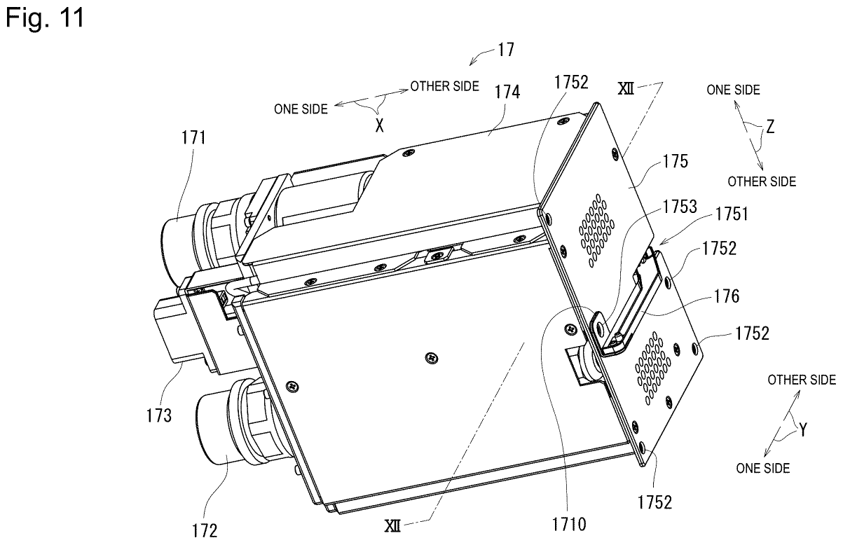

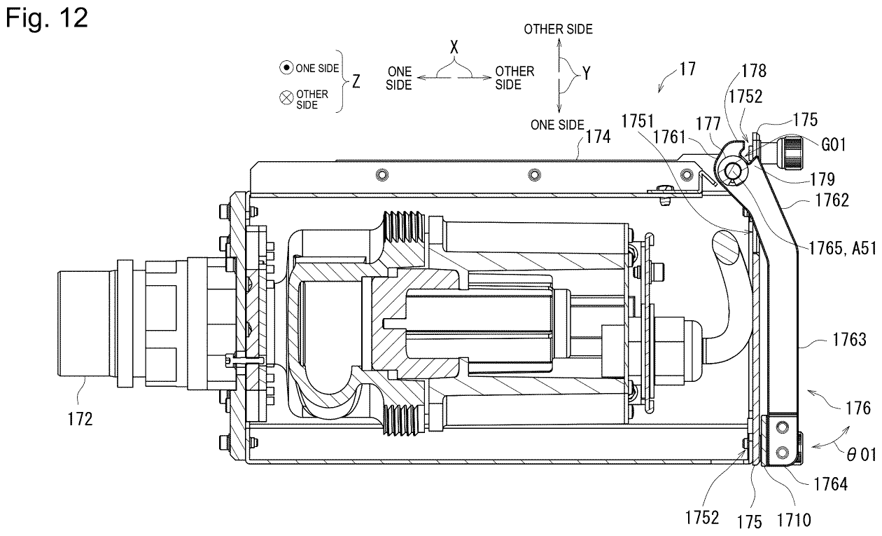

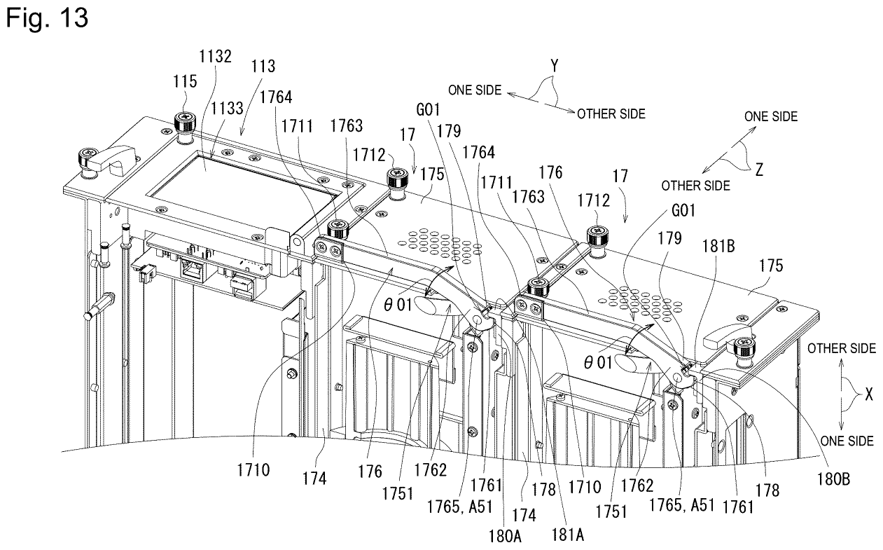

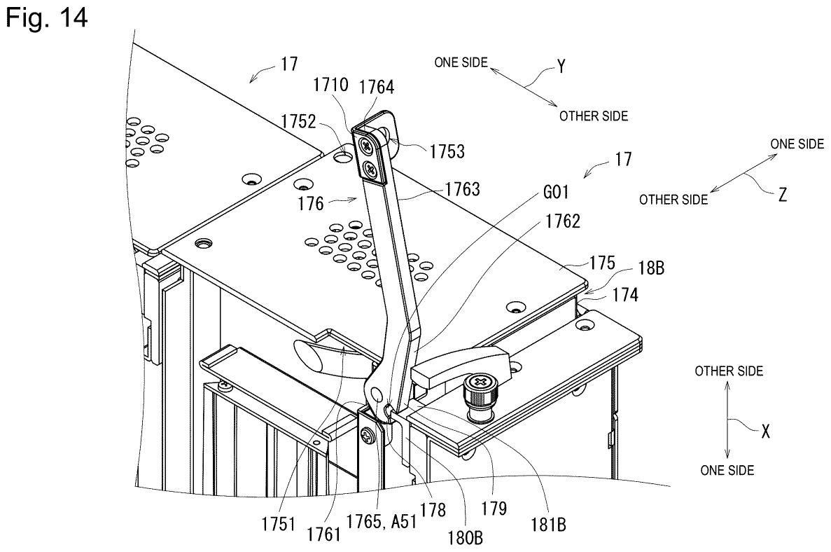

FIG. 11 is an enlarged perspective view of one pump 17 shown in FIG. 7. FIG. 12 is a transverse cross-sectional view of the pump 17 taken along line XII-XII shown in FIG. 11. FIG. 13 is a view showing a state where a first stopper 178 shown in FIG. 11 is at a first position. FIG. 14 is a view showing a state where the first stopper 178 shown in FIG. 11 is at a second position. FIGS. 11 and 12 show the pump 17 in a mounted state for the purpose of easy understanding. However, FIGS. 11 and 12 do not show the housing 15.

As shown in FIGS. 11 to 14, the pump 17 includes a housing 174, a panel 175, a lever 176, a support portion 177, the first stopper 178, and a second stopper 179 as other parts of the fixing structure. That is, the CDU 1 includes the first stopper 178 and the second stopper 179.

As clearly shown in FIGS. 11 and 12, the housing 174 has a substantially rectangular cuboid shape relatively long in the X direction, and has a dimension that can be inserted into and removed from the mounting assemblies 18A and 18B (see FIG. 10) in the Z direction, the X direction, and the Y direction. The housing 174 accommodates the internal flow path, the pump rotor, and the pump motor of the pump 17. From one end in the X direction of the housing 174, the suction port 171, the discharge port 172, and the connector 173 protrude in one side in the X direction.

The panel 175 is fixedly attached to the other end in the X direction of the housing 174. That is, the housing 174 includes the panel 175. The housing 174 is an example of the “second housing” in the present disclosure. The panel 175 is an example of the “second panel” of the present disclosure. In the example embodiment, the panel 175 has a plate shape thin in the X direction and extending in both the Z direction and the Y direction. The panel 175 has a substantially rectangular shape in plan view from the X direction. The dimensions in the Z direction and the Y direction of the panel 175 are substantially the same as the dimensions in the Z direction and the Y direction of the openings 1521A and 1521B, respectively.

A slit 1751 is formed in the panel 175. The slit 1751 is directed from the other end in the Y direction toward one end in the Y direction of the panel 175. The slit 1751 extends to a position on the other side in the Y direction relative to the center in the Y direction of the panel 175. One end in the Z direction of the slit 1751 is positioned around one end in the Z direction of the protrusions 181A and 181B (see FIG. 10) included in the housing 15. The other end in the Z direction of the slit 1751 is positioned around the other end in the Z direction of the protrusions 181A and 181B (see FIG. 10).

In the peripheral edge of the panel 175, screw holes 1752 are formed at the Z direction position and Y direction position substantially the same as the screw holes 191. A screw hole 1753 is formed substantially at the center in the Z direction at one end in the Y direction of the panel 175.

As shown in FIGS. 11 to 14, the lever 176 has a rod shape relatively thin in the Z direction and relatively long in the Y direction. The lever 176 includes a base end 1761, a first part 1762, a second part 1763, a tip end 1764, and a shaft 1765.

The base end 1761 is positioned on one side in the X direction relative to the panel 175. The first part 1762 extends substantially straight to one side in the X direction relative to the panel 175 from the base end 1761 through the slit 1751. The second part 1763 is connected to the tip end of the first part 1762. The second part 1763 is bent with respect to the first part 1762. The second part 1763 extends to the tip end 1764 of the lever 176.

The shaft 1765 is positioned slightly away toward the second part 1763 from the base end 1761 in the first part 1762. The shaft 1765 includes a rotation axis A51 along the Z direction. The Z direction is an example of the “second direction” of the present disclosure. The first part 1762, that is, the lever 176 is supported on the panel 175 by the support portion 177 rotatably in a circumferential direction θ01 of the rotation axis A51.

In detail, the support portion 177 supports the shaft 1765 such that the second part 1763 is rotatable between a creepage position in the circumferential direction θ01 (see FIGS. 11 to 13) and a separation position (see FIG. 14). Both the creepage position and the separation position are positions of the second part 1763. The creepage position is a position where in particular, the second part 1763 extends along the panel 175 on the other side in the X direction. The separation position is a position where in particular, the second part 1763 is separated from the panel 175 in the circumferential direction θ01. In detail, when in the separation position, the second part 1763 intersects with the panel 175 at a relatively large angle and extends in the X direction (see FIG. 14). This enables the human to easily insert and remove the pump 17 into and from the mounting assemblies 18A and 18B (see FIG. 10).

The first stopper 178 is movable in the circumferential direction θ01 between the first position and the second position. The first position is a position of the first stopper 178 shown in FIGS. 12 and 13, and is a position where the first stopper 178 does not overlap with the protrusions 181A and 181B on one side in the X direction. One side in the X direction is a direction from the openings 1521A and 1521B toward the mounting position P10. The second position is a position of the first stopper 178 shown in FIG. 13, and is a position where the first stopper 178 overlaps with the protrusions 181A and 181B on one side in the X direction and on one side in the X direction relative to the protrusions 181A and 181B. Therefore, the pump 17 is not removed from the housing 15 by moving the first stopper 178 to the second position when the pump 17 has reached the mounting position P10. This improves usability of the CDU 1. One side in the X direction and the other side in the X direction are examples of the “one side in the first direction” and the “other side in the first direction” of the present disclosure.

The first stopper 178 preferably comes into contact with the protrusions 181A and 181B from one side in the X direction in a state of being at the second position. Therefore, since the pump 17 is reliably positioned at the mounting position P10, it is not removed from the mounting assemblies 18A and 18B.

The first stopper 178 is preferably provided around the shaft 1765, that is, the rotation axis A51. Since the first stopper 178 is near the lever 176, the pump 17 is downsized.

The second stopper 179 is movable in the circumferential direction θ01 between a third position and a fourth position. The third position is a position of the second stopper 179 shown in FIG. 13, and is a position where the second stopper 179 does not overlap with the protrusions 181A and 181B in the X direction. The fourth position is a position of the second stopper 179 shown in FIG. 14, and is a position where the second stopper 179 overlaps with the protrusions 181A and 181B in the X direction and on the other side in the X direction relative to the protrusions 181A and 181B.

The second stopper 179 is at the fourth position when the first stopper 178 is at the first position. The second stopper 179 is at the third position when the first stopper 178 is at the second position. When the pump 17 is at the mounting position P10 and the second stopper 179 is at the fourth position, the second stopper 179 comes in contact with the protrusions 181A and 181B on the other side in the X direction relative to the protrusions 181A and 181B. Therefore, the second stopper 179 regulates rotation of the lever 176 in the circumferential direction θ01. Therefore, the human can easily remove the pump 17 from the mounting assemblies 18A and 18B.

The pump 17 further includes a base portion 1710 (see FIGS. 11 and 13) and a screw 1711 (see FIG. 13). The screw 1711 is an example of the “first fixing tool” in the present disclosure.

As shown in FIGS. 11 and 13, the base portion 1710 is fixedly attached near the tip end 1764 of the lever 176. The base portion 1710 has a plate shape thin in the X direction when the second part 1763 is positioned at the creepage position (see FIG. 13). In plan view from the X direction, the base portion 1710 has a substantially rectangular shape, and a screw hole penetrating in the X direction is formed. The screw hole of the base portion 1710 overlaps in the X direction with the screw hole 1753 formed in the panel 175. The screw 1711 is inserted into the screw hole of the base portion 1710 and the screw hole 1753 and screwed when the second stopper 179 is at the third position. As a result, the base portion 1710 and the panel 175 are fastened with the screw 1711. That is, the screw 1711 fixes the lever 176 to the panel 175. Therefore, the second stopper 179 is prevented from moving from the third position due to vibration or the like. That is, the first stopper 178 is prevented from moving from the second position. As a result, the pump 17 becomes less likely to be removed from the housing 15.

When the pump 17 is at the mounting position P10 (see FIG. 9), the screw hole 1752 (see FIG. 11) overlaps in the X direction with the screw hole 191 (see FIG. 10) formed in the peripheral edge of the openings 1521A and 1521B in the housing 15. The CDU 1 further includes a screw 1712 as a fixing structure. The screw 1712 is an example of the “second fixing tool” in the present disclosure. The screw 1712 is inserted into the screw holes 1752 and 191 and screwed in the state where the pump 17 is at the mounting position P10. As a result, the housing 15 and the pump 17 are fastened with the screw 1712. That is, the screw 1712 fixes the panel 175 of the pump 17 to the edges of the openings 1521A and 1521B in the housing 15. Therefore, it is possible to more reliably suppress the pump 17 from being removed from the housing 15. It is possible to suppress the position of the pump 17 from being displaced due to vibration or the like.

Next, the first stopper 178 and the second stopper 179 will be described in more detail. The first stopper 178 protrudes outward the housing 15 at a position closer to the base end 1761 than the second stopper 179. The second stopper 179 protrudes outward the housing 15 at a position closer to the second part 1763 than the first stopper 178 in the first part 1762. The first stopper 178 and the second stopper 179 face each other in the circumferential direction θ01. That is, a gap G01 is formed between the first stopper 178 and the second stopper 179. The gap G01 is larger than the X direction dimensions of the protrusions 181A and 181B in the circumferential direction θ01. With this configuration, the pump 17 can be inserted into and removed from the mounting assemblies 18A and 18B.

When mounting the pump 17, the human first inserts the pump 17 into the accommodation spaces A21 and A22 through the openings 1521A and 1521B when the lever 176 is positioned between the creepage position (see FIGS. 11 to 13) and the separation position (see FIG. 14) in the circumferential direction θ01. Thereafter, the human moves the pump 17 toward the mounting position P10 on one side in the X direction in the accommodation spaces A21 and A22. In the movement process, the first stopper 178 is positioned at the first position until the panel 175 of the pump 17 approaches the panel 152 at a predetermined distance from the other side in the X direction (see FIG. 13). Accordingly, the second stopper 179 moves to the fourth position (see FIG. 13). In this state, the human further moves the pump 17 on one side in the X direction until the second stopper 179 comes in contact with the protrusions 181A and 181B from the other side in the X direction (see FIG. 13).

Thereafter, the human brings the lever 176 close to the creepage position in response to the contact of the second stopper 179 with the protrusions 181A and 181B (see FIGS. 11 to 13). At this time, since the gap G01 is formed between the first stopper 178 and the second stopper 179, the lever 176 can be brought close to the creepage position. That is, the first stopper 178 is movable toward the second position, and the second stopper 179 is movable toward the third position (see FIG. 14).

When the human further brings the lever 176 close to the creepage position, the first stopper 178 reaches the second position and comes in contact with the protrusions 181A and 181B from one side in the X direction. The second stopper 179 reaches the third position.

Thereafter, the human fastens the base portion 1710 and the panel 175 with the screw 1711, and then fixes the panel 175 of the pump 17 to the housing 15 with the screw 1712 (see FIG. 13).

When mounting the pump 17, the human grips the second part 1763 of the lever 176 by hand, and mounts the pump 17 to the mounting position P10 on one side in the X direction in the accommodation spaces A21 and A22. Here, the distance from the rotation axis A51 to the first stopper 178 is shorter than the distance from the rotation axis A51 to the second part 1763. Since the distance to the first stopper 178 is relatively short, the first stopper 178 does not relatively occupy a space in the internal space A11 at the time of mounting. Since the distance to the second part 1763 is relatively long, the pump 17 is easily mounted to the mounting position P10 by the human based on the leverage principle.

When removing the pump 17, the human removes the screw 1712 from the panel 175 of the pump 17 and the housing 15, and then removes the screw 1711 from the base portion 1710 and the panel 175.

Thereafter, the human slightly rotates the lever 176 from the creepage position in the circumferential direction θ01 toward the separation position in the circumferential direction θ01. As a result, the first stopper 178 moves from the second position to the first position, and the second stopper 179 moves from the third position to the fourth position. Furthermore, the panel 175 of the pump 17 slightly moves on the other side in the X direction relative to the panel 152 of the housing 15.

Thereafter, the human further rotates the lever 176 in the circumferential direction θ01 toward the separation position (see FIG. 14). Accordingly, the first stopper 178 reaches the first position, and the second stopper 179 moves to the fourth position. Thereafter, the human removes the pump 17 from the accommodation spaces A21 and A22 through the openings 1521A and 1521B.

As shown in FIGS. 8 and 10, the CDU 1 includes a pair of guide rails 110 and a guide rail 111 in each of the mounting assemblies 18A and 18B. In the mounting assembly 18A, the pair of guide rails 110 are provided on the panel 153, and the guide rail 111 is provided on the partition walls 181 and 182. In the mounting assembly 18B, the pair of guide rails 110 are provided on the panel 153, and the guide rail 111 is provided on the panel 156 and the partition wall 181. Each guide rail 110 sandwiches the other end in the Z direction of the housing 174 of the pump 17 (see FIGS. 6 and 11) and guides movement in the X direction of the housing 174. Each guide rail 111 is engaged with the other face in the Y direction of the housing 174 of the pump 17 and guides movement in the X direction of the housing 174. The panels 153 and 156 and the partition walls 181 and 182 are examples of the “wall” in the present disclosure.

The guide rails 110 and 111 facilitate mounting of the pump 17 to the mounting position P10. In particular, the guide rail 110 suppresses the positional displacement in the Y direction of the pump 17 of the mounting position P10. Since the guide rails 110 and 111 suppress the positional displacement in both the Z direction and the Y direction of the pump 17, the suction port 171 of the pump 17 is reliably connected to the sockets 74A and 74B, and each discharge port 172 is reliably connected to the sockets 75A and 75B.

As shown in FIGS. 8 and 10, the pair of guide rails 110 face each other in the Y direction. The interval in the Y direction between the pair of guide rails 110 is the widest at one end in the X direction and/or the other end in the X direction. This makes it easy to guide the pump 17 between the guide rails 110. In detail, in a part including the other end in the X direction in the pair of guide rails 110, the interval in the Y direction becomes wider as the other end in the X direction. In a part including one end in the X direction in the pair of guide rails 110, the interval in the Y direction becomes wider as one end in the X direction. This makes it easy to smoothly guide the pump 17 between the guide rails 110.

As clear from FIGS. 5 and 10, the CDU 1 further includes a receiving portion 112 that receives the primary refrigerant on the other side in the Z direction relative to the suction port 171 and the discharge port 172 of the pump 17. The other side in the Z direction is a vertically lower direction. Due to the receiving portion 112, even if the primary refrigerant leaks from the suction port 171 and the discharge port 172, the primary refrigerant is less likely to spread in the housing 15.

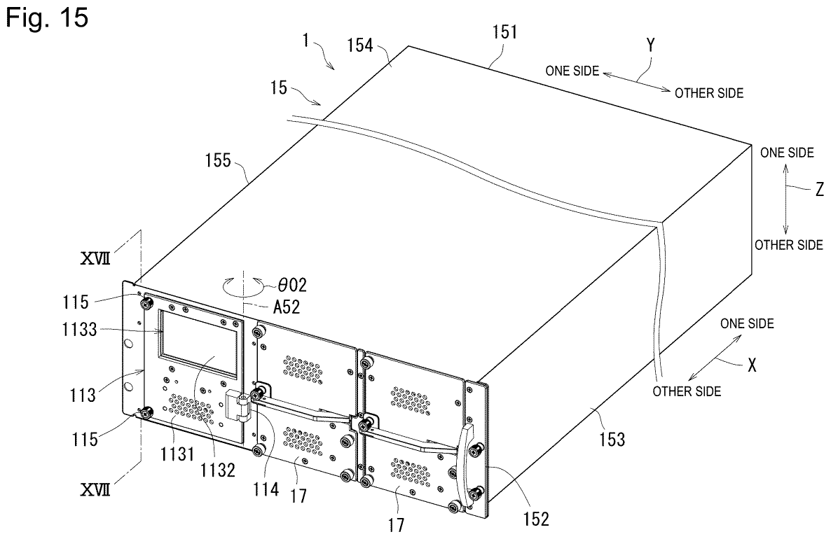

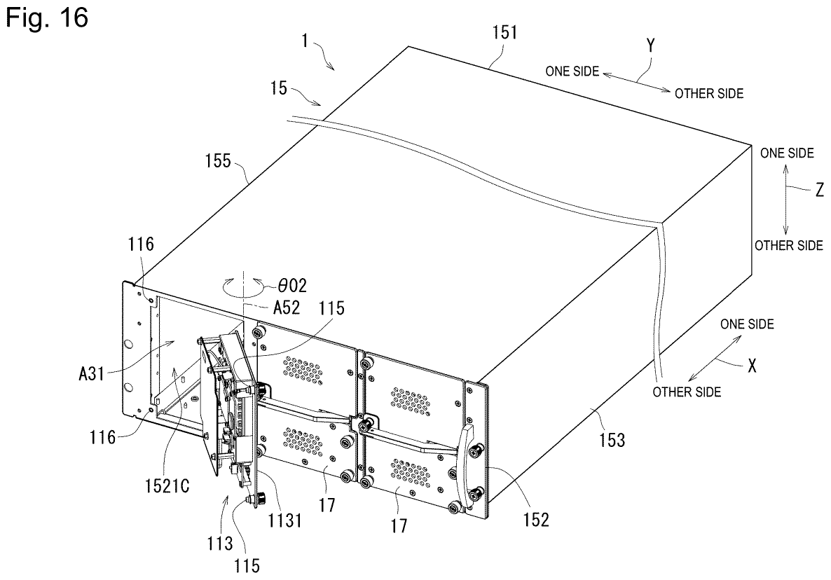

FIG. 15 is a perspective view showing a display assembly 113 in a close state. FIG. 16 is a perspective view showing the display assembly 113 in an open state. As shown in FIGS. 15 and 16, the CDU 1 further includes the display assembly 113 and a support portion 114. The CDU 1 is an example of the “electronic equipment” in the present disclosure.

As shown in FIG. 16, an opening 1521C is further formed at a position different from the openings 1521A and 1521B in the panel 152. The opening 1521C is positioned on one side in the Y direction relative to the openings 1521A and 1521B (see FIG. 6). The opening 1521C is another example of the “first opening” in the present disclosure. The opening 1521C has a substantially rectangular shape in plan view from the X direction.

As shown in FIGS. 15 and 16, the display assembly 113 includes a panel 1131 and the touch screen 1132.

The panel 1131 has an opening 1133 having a substantially rectangular shape in plan view from the X direction. In the example embodiment, the Z direction dimension and the Y direction dimension of the panel 1131 are slightly larger than the same direction dimensions of the opening 1521C.

The touch screen 1132 displays an image. The image includes at least one of a character, a picture, a figure, and a photograph. The touch screen 1132 is a flat panel display such as a liquid crystal display or an organic EL display. The touch screen 1132 is positioned slightly away in one side in the X direction from the opening 1521C. In this position, the touch screen 1132 is fixed to the panel 1131 via a spacer (not shown) made of an electrically insulating material.

The support portion 114 is, for example, one hinge, and movably supports the panel 1131 between a close position (see FIG. 15) where the opening 1521C is closed and an open position (see FIG. 16) where the opening 1521C is opened. In detail, the support portion 114 rotatably supports the panel 1131 in a circumferential direction θ02 of a rotation axis A52 extending in the Z direction along the edge of the opening 1521C in the panel 1131 between the close position and the open position.

The support portion 114 makes it possible to provide the CDU 1 with good usability. In detail, when the panel 1131 is in the close position, each screw portion of a thumb screw 115 is screwed into a screw hole 116. As a result, the display assembly 113 is fastened to the panel 152 of the housing 15. That is, the display assembly 113 is provided on the panel 152. The panel 152 is an example of the “panel” of the present disclosure. Therefore, since the openings 1521A and 1521B and the display assembly 113 are provided in the same panel 152, usability is good. In detail, by facing the panel 152, the human can insert and remove the pump 17 and visually recognize the display assembly 113. Therefore, usability is good.

Entry of foreign matters from the outside to the inside of the housing 15 is prevented. The human loosens the thumb screw 115 by manual operation, and then moves the panel 1131 from the close position to the open position. As a result, the human can access an internal space A31 of the housing 15 from the opening 1521C. That is, the human can confirm and maintain the components in the housing 15.

In the example embodiment, the display assembly 113 can be opened and closed with respect to the panel 152. However, the present disclosure is not limited to this, and the display assembly 113 may be fixed to the panel 152.

As shown in FIG. 1, the CDU 1 is accommodated in the rack 9, for example. The rack 9 has a wall 91. The wall 91 partitions the internal space A31 of the rack 9 from the outside. The internal space A31 is opened to the outside through an opening 92 formed by the wall 91. The CDU 1 is accommodated in the rack 9 such that the openings 1521A and 1521B and the display assembly 113 (see FIG. 15) in the close state face the same direction as the opening 92 (see FIG. 1). Therefore, since the human can insert and remove the pump 17 through the opening 92 and can visually recognize the display assembly 113, the usability of the CDU 1 is further improved.

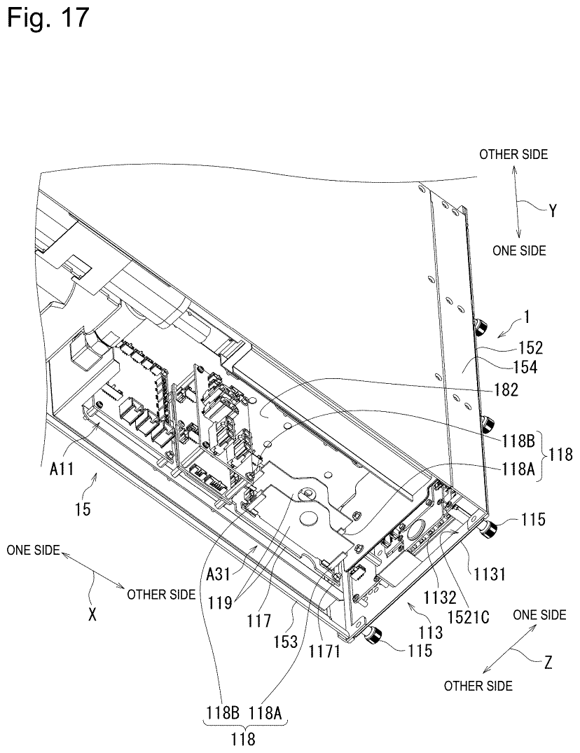

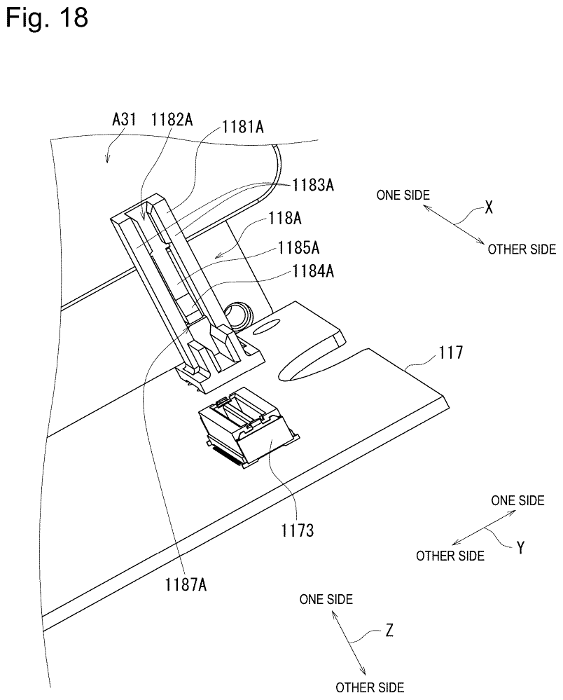

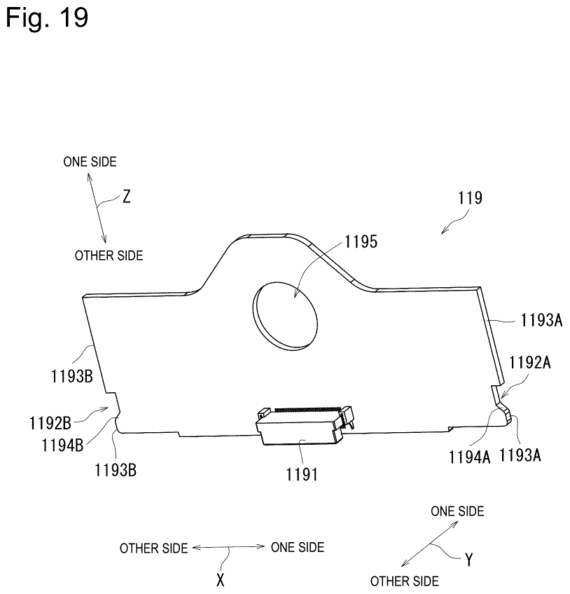

FIG. 17 is a longitudinal cross-sectional view of the CDU 1 taken along line XVII-XVII shown in FIG. 15. FIG. 18 is a perspective view showing a detailed configuration of a mounting assembly 118A shown in FIG. 17. FIG. 19 is a perspective view showing a detailed configuration of a second circuit board 119 shown in FIG. 17.

As shown in FIGS. 17 to 19, in the internal space A11, the panels 152 and 155 (see FIG. 16) and the partition wall 182 define the internal space A31 on one side in the X direction of the display assembly 113 in the panel close state. That is, the housing 15 defines the internal space A31. The internal space A31 is an example of the “internal space” in the present disclosure.

The CDU 1 includes, in the internal space A31, a first circuit board 117, a mounting assembly 118, and the second circuit board 119.

The first circuit board 117 extends in both the X direction and the Y direction in the internal space A31. In detail, the first circuit board 117 is installed in the panel 153 of the housing 15 via a spacer 1171 or the like. The first circuit board 117 is positioned on one side in the X direction relative to the opening 1521C. The first circuit board 117 is positioned closer to the panel 153 than the panel 154 in the Z direction. The first circuit board 117 is made of an electrically insulating material. A conductor wiring is formed on the first circuit board 117 or in the first circuit board 117. Various electronic components and a connector 1173 are mounted on the wiring. The connector 1173 (see FIG. 18) is electrically connected to a connector 1191 (see FIG. 19) mounted on second circuit board 119.

One mounting assembly 118 has a pair of mounting assemblies 118A and 118B. The mounting assemblies 118A and 118B are attached to the first circuit board 117 and electrically connect the second circuit board 119 to the first circuit board 117. Each of the mounting assemblies 118A and 118B extends in one side in the Z direction from a face 1172 facing one side in the Z direction in the first circuit board 117. One side in the Z direction is an orientation from the first circuit board 117 toward a projection portion 1184A in the Z direction, and is another example of the “one side in the first direction” in the present disclosure. On the other hand, the other side in the Z direction is an orientation from the projection portion 1184A toward the first circuit board 117, and is another example of the “other side in the first direction” in the present disclosure. The mounting assemblies 118A and 118B are positioned apart from each other in the X direction. In detail, the mounting assembly 118A is positioned on the other side in the X direction relative to the mounting assembly 118B. The mounting assemblies 118A and 118B are separated by a first specific distance in the X direction. Details of the first specific distance will be described later.

The mounting assembly 118A includes a guide portion 1181A. The guide portion 1181A extends from the first circuit board 117 along one side in the Z direction intersecting with the first circuit board 117. The guide portion 1181A includes a groove 1182A guiding an edge 1193A of the second circuit board 119. The mounting assembly 118A has a face 1183A facing one side in the X direction. The face 1183A faces the mounting assembly 118B. The groove 1182A is recessed from the face 1183A to the other side in the X direction, and extends from one end in the Z direction to near the other end in the Z direction of the mounting assembly 118A. The Y direction dimension of the groove 1182A is substantially the same as the thickness of the second circuit board 119.

The mounting assembly 118A further includes the projection portion 1184A and an elastic deformation portion 1185A. The projection portion 1184A is provided in the groove 1182A, and is fitted into a recess portion 1192A of the second circuit board 119. The mounting assembly 118A further includes the elastic deformation portion 1185A. In a process where an edge 1193 is guided in the groove 1182A, the elastic deformation portion 1185A retracts the projection portion 1184A from the groove 1182A by the edge 1193 being elastically deformed by coming into contact with the projection portion 1184A. In detail, a through hole 1187A is formed at the bottom of the groove 1182A. The elastic deformation portion 1185A extends from one end in the Z direction or the other end in the Z direction of the through hole 1187A to the other side in the Z direction or one side in the Z direction. The projection portion 1184A is formed at an extension end of the elastic deformation portion 1185A and protrudes to one side in the X direction. Due to this, the projection portion 1184A protrudes to one side in the X direction relative to the bottom of the groove 1182A.

The mounting assemblies 118A and 118B have identical shapes to each other. The mounting assembly 118B is substantially symmetrical to the mounting assembly 118B in the X direction. Therefore, the mounting assembly 118B also includes the guide portion 1181A, the projection portion 1184A, and the elastic deformation portion 1185A.

In the example embodiment, two sets of the mounting assemblies 118 are attached to the first circuit board 117. In detail, the two sets of mounting assemblies 118 are positioned apart from each other in the Y direction.

The second circuit board 119 is detachably mounted to the pair of mounting assemblies 118A and 118B. The second circuit board 119 extends in both the X direction and the Z direction in the internal space A31 at the time of mounting to the pair of mounting assemblies 118A and 118B. Hereinafter, the second circuit board 119 at the time of mounting will be described for easy understanding. Hereinafter, unless otherwise specified, the term “second circuit board 119” means the second circuit board 119 at the time of mounting to the pair of mounting assemblies 118A and 118B.

Similarly to the first circuit board 117, the second circuit board 119 is made of an electrically insulating material and includes conductor wiring. On the wiring of the second circuit board 119, various electronic components and the connector 1191 are mounted on the wiring. The connector 1191 is mounted along the other end in the Z direction of the second circuit board 119 and is electrically connected to the connector 1173.

The second circuit board 119 has substantially symmetrical shapes to each other in the X direction. The X direction dimension of the second circuit board 119 substantially coincides with the first specific distance. The second circuit board 119 has recess portions 1192A and 1192B formed in edges 1193A and 1193B on one side in the X direction and the other side in the X direction. When the second circuit board 119 is mounted, the projection portions 1184A and 1184B are fitted into the recess portions 1192A and 1192B.

By applying an external force in the Z direction to the second circuit board 119 with the second circuit board 119 and the mounting assemblies 118A and 118B, the human can insert and remove the second circuit board 119 into and from the mounting assemblies 118A and 118B. In detail, the human inserts the other end in the Z direction of the second circuit board 119 into the grooves 1182A and 1182B from one side in the Z direction, and applies an external force on the other side in the Z direction to the second circuit board 119. Accordingly, the edges 1193A and 1193B of the second circuit board 119 move on the other side in the Z direction while being guided by the grooves 1182A. The edges 1193A and 1193B come into contact with the projection portion 1184A in the process of being guided in the groove 1182A in the mounting assemblies 118A and 118B. As a result, in the mounting assemblies 118A and 118B, the elastic deformation portion 1185A is elastically deformed, and the projection portion 1184A retreats from each groove 1182A on the other side in the X direction and one side in the X direction. When the edges 1193A and 1193B of the second circuit board 119 are further moved on the other side in the Z direction, the recess portions 1192A and 1192B of the second circuit board 119 reach the projection portions 1184A and 1184B. Accordingly, in the mounting assemblies 118A and 118B, the projection portion 1184A returns to the groove 1182A, and the projection portion 1184A is engaged with the recess portions 1192A and 1192B. At this time, the connectors 1173 and 1191 are connected to each other. Due to this, the second circuit board 119 is mounted on the mounting assemblies 118A and 118B.

The second circuit board 119 extends along the X direction in a state of being mounted to the mounting assemblies 118A and 118B. The plurality of second circuit boards 119 are arrayed in the Y direction intersecting with the X direction in the state of being mounted to the mounting assemblies 118A and 118B. When the plurality of second circuit boards 119 are arrayed in the Y direction, the human can easily insert and remove each of the second circuit boards 119 through the opening 1521C. When the plurality of second circuit boards 119 are arrayed in the X direction, it is difficult for the human to insert and remove the second circuit boards 119 except the second circuit board 119 closest to the opening 1521C.

The plurality of second circuit boards 119 are arrayed on the face on one side in the Z direction of the first circuit board 117 in the state of being mounted to the mounting assemblies 118A and 118B. Therefore, the human becomes able to easily insert and remove each of the second circuit boards 119.

When removing the second circuit board 119 from the mounting assemblies 118A and 118B, the human only needs to apply an external force on one side in the Z direction to the second circuit board 119.

The recess portions 1192A and 1192B preferably have first inclined portions 1194A and 1194B inclined on the other side in the Z direction of the one side in the Z direction and the other side in the Z direction. The projection portions 1184A and 1184B have second inclined portions 1186A and 1186B inclined on one side in the Z direction of the one side in the Z direction and the other side in the Z direction.

The first inclined portions 1194A and 1194B are inclined to be closer to the edges 1193A and 1193B as the position is on the other side in the Z direction. The second inclined portions 1186A and 1186B are inclined to be farther from the elastic deformation portions 1185A and 1185B as the portion is on the other side in the Z direction.

The first inclined portions 1194A and 1194B and the second inclined portions 1186A and 1186B allow the second circuit board 119 to be more easily inserted into and removed from the mounting assemblies 118A and 118B.

A through hole 1195 is formed in the second circuit board 119. The human can more easily remove the second circuit board 119 from the mounting assemblies 118A and 118B. The through hole 1195 is preferably formed near one end in the Z direction and has a diameter through which a human finger can pass.

The second circuit board 119 preferably has an electronic component mounted at a position spaced away from the through hole 1195. As the electronic component, FIG. 19 shows the connector 1191. This makes it difficult for the human to touch the electronic component.

As shown in FIG. 2, the CDU 1 further includes the power supply unit 201. In the example embodiment, the number of the power supply units 201 is two. The number of the power supply units 201 may be at least one. The two power supply units 201 are preferably manufactured in accordance with the same specifications.

Each power supply unit 201 is a power supply circuit or the like. Each power supply unit 201 generates a first DC voltage from an AC voltage supplied from a commercial power supply, for example. On the other hand, each power supply unit 201 generates a second DC voltage lower than the first DC voltage from the AC voltage. In the example embodiment, the first DC voltage and the second DC voltage are 54 V and 3.3 V, respectively. The first DC voltage is supplied to the pump 17, for example. The second DC voltage is supplied to the control unit 202, for example.

In the example embodiment, the two power supply units 201 are stacked in the Z direction in the housing 15. The two power supply units 201 are positioned between the panels 153 and 154 in the Z direction. The two power supply units 201 are positioned on one side in the X direction relative to the individual pipe 81 and the common pipe 72 in the X direction, and are exposed from the panel 151. The two power supply units 201 are positioned closer to the panel 156 than the panel 155 in the Y direction. In detail, the two power supply units 201 are close to the panel 156 via a slight gap (see FIG. 4).

The two power supply units 201 may be insertable into and removable from the housing 15 in the same manner as that of the pump 17. The two power supply units 201 may be installed in the internal space A11.

The control unit 202 includes a microcomputer and a memory that are not shown, and operates with the second DC voltage. The microcomputer and the memory are mounted on the first circuit board 117 and/or the second circuit board 119. The microcomputer controls at least the operation of each pump 17 in accordance with a program stored in the memory.

In detail, the control unit 202 generates and transmits, to the touch screen 1132, data indicating various images to be displayed on the touch screen 1132. The touch screen 1132 displays various images in accordance with the received data.

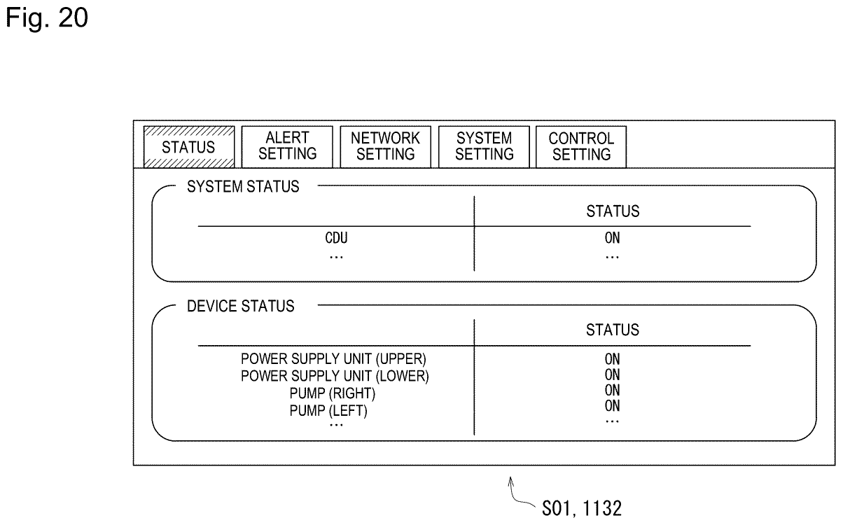

FIG. 20 is a view showing an example of the image S01 displayed on the touch screen 1132. As shown in FIG. 20, the image S01 indicates an operation status of the CDU 1 as a system status. The image S01 additionally shows operation statuses of the two power supply units 201 and the two pumps 17 as device statuses.

As shown in FIGS. 6 to 8, the CDU 1 further includes a tank 203. The tank 203 stores the primary refrigerant.

In the example embodiment, the tank 203 is positioned among the panel 154 (see FIG. 3), the individual pipe 82 (see FIG. 4), and the heat exchanger 16 in the Z direction. The tank 203 is positioned near the panel 151 between the panels 151 and 152 in the X direction. The tank 203 is positioned closer to the panel 155 than the panel 156 in the Y direction. In detail, the tank 203 is close to the panel 155 via a slight gap.

As shown in FIG. 2, in association with the tank 203, the CDU 1 includes, in the panel 151, a tank injection hole 204, a liquid level check window 205, and an air vent valve 206. The tank injection hole 204 is used to replenish the tank 203 with the primary refrigerant. The liquid level check window 205 is made of a translucent material and shows the liquid level in the tank 203. The air vent valve 206 releases air in the tank 203 to the outside.

In the fixing structure of the pump 17 in the example embodiment, as shown in FIGS. 11 to 14, the lever 176 is supported on the panel 175 by the support portion 177 rotatably in the circumferential direction θ01 of the rotation axis A51 along the Z direction. The first stopper 178 is movable in the circumferential direction θ01 between the first position and the second position. The second stopper 179 is movable in the circumferential direction θ01 between the third position and the fourth position.

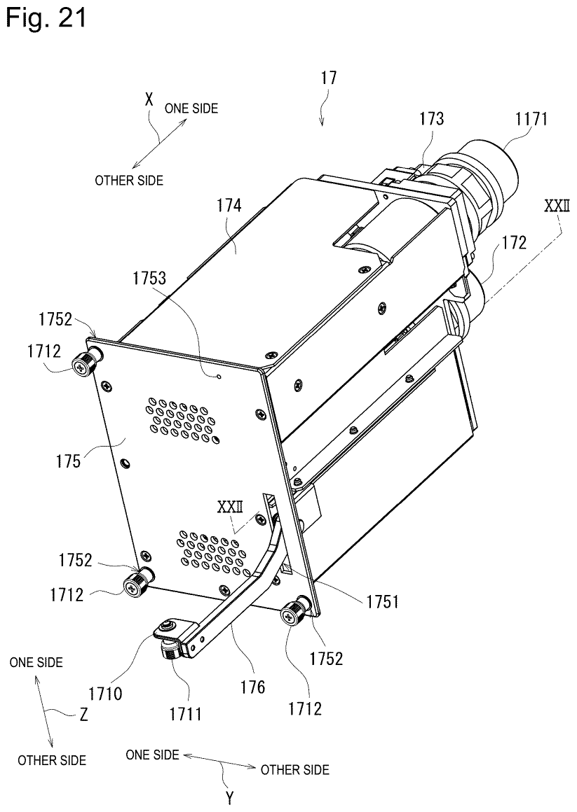

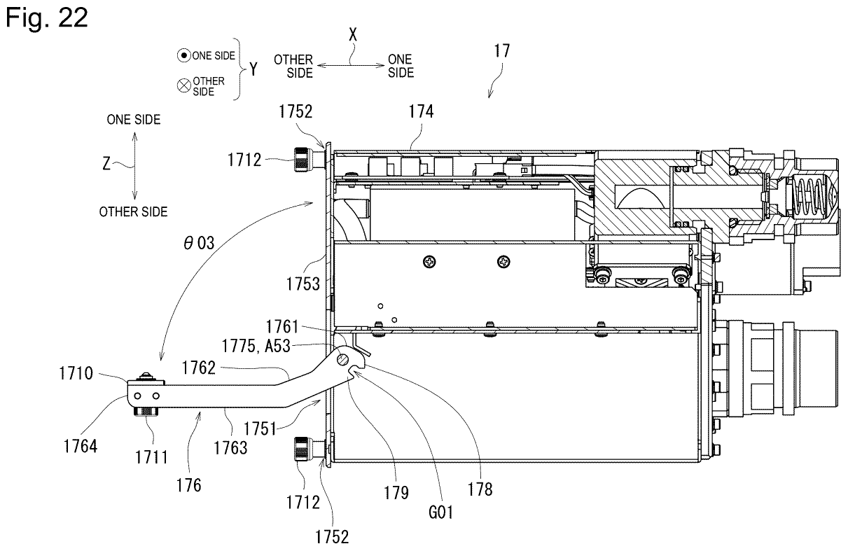

FIG. 21 is a perspective view of the pump 17 according to a modification. FIG. 22 is a longitudinal cross-sectional view of the pump 17 taken along line XXII-XXII in FIG. 21. As shown in FIGS. 21 and 22, the lever 176 may be supported on the panel 175 by the support portion 177 rotatably in a circumferential direction θ03 of a rotation axis A53 along the Y direction. The first stopper 178 may be movable in the circumferential direction θ03 between the first position and the second position. The second stopper 179 may be movable in the circumferential direction θ03 between the third position and the fourth position. In this case, the protrusion 181B protrudes inward of the opening 1521B relative to the edge 157B of the opening 1521B in the housing 15. The protrusion 181B has a plate shape thin in the X direction and expanding along the opening 1521B. That is, the protrusion 181B extends in both the Z direction and the Y direction. The protrusion 181B has, for example, a substantially rectangular shape in plan view from the X direction.

The drawings schematically mainly show each element in order to facilitate understanding of the present disclosure, and the thickness, length, number, interval, and the like of each element that are shown may be different from the actual ones for convenience of the drawings. The configuration of each element shown in the above example embodiment is an example and is not particularly limited, and it goes without saying that various modifications can be made without substantially departing from the effects of the present disclosure.

The present technology can also adopt the following configurations.

(1) A refrigerant circulation device including a first housing including a first opening, a protrusion protruding from the first housing, and a pump that is movable in a first direction in an internal space of the first housing through the first opening and is mounted at a mounting position that is a position of one side in the first direction relative to the first opening in the internal space, in which the pump includes a first stopper that is movable between a first position that does not overlap with the protrusion in one side of the first direction and a second position that overlaps with the protrusion in one side of the first direction and is on one side in the first direction relative to the protrusion.

(2) The refrigerant circulation device according to (1), in which the first stopper comes into contact with the protrusion in a state of being in the second position.

(3) The refrigerant circulation device according to (1) or (2), in which the pump further includes a second housing including a second panel on the other side in the first direction, and a lever supported on the second panel rotatably about a shaft along a second direction intersecting the first direction, and the first stopper is provided around the shaft in the lever.

(4) The refrigerant circulation device according to any of (1) to (3), in which the lever further includes a second stopper movable between a third position not overlapping with the protrusion in the first direction and a fourth position overlapping with the protrusion in the first direction and on the other side in the first direction relative to the protrusion, the second stopper is positioned in the fourth position when the first stopper is in the first position, is positioned in the third position when the first stopper is in the second position, and comes in contact with the protrusion on the other side in the first direction relative to the protrusion when the pump is in the mounting position and in the fourth position.

(5) The refrigerant circulation device according to (4), in which the pump further includes a first fixing tool that fixes the lever to the second panel when the second stopper is at the third position.

(6) The refrigerant circulation device according to any of (1) to (5), further including a second fixing tool that fixes the second panel of the pump to the first housing.

(7) The refrigerant circulation device according to any of (1) to (6), in which the first housing includes a wall partitioning the internal space, and a pair of guide rails provided on the wall and guiding the second housing in the first direction.

(8) The refrigerant circulation device according to (7), in which the pair of guide rails oppose each other in a third direction intersecting with the first direction, and an interval in the third direction between the pair of guide rails is widest at one end and/or an other end in the first direction.

(9) The refrigerant circulation device according to any of (1) to (8), in which the pump includes a suction port and a discharge port for a refrigerant, and the refrigerant circulation device further includes a receiving portion that receives the refrigerant below the suction port and the discharge port.

(10) The refrigerant circulation device according to any of (1) to (9), in which the protrusion protrudes inward of the first opening relative to an edge of the first opening in the first housing.

(11) A refrigerant circulation device including a housing including a first opening, a pump mounted in the housing through the first opening, and a display assembly that is provided in the housing and displays a screen.

(12) The refrigerant circulation device according to (11), in which the refrigerant circulation device is accommodated in a rack, the rack includes a wall partitioning an internal space opened through a second opening, and the first opening and the display assembly oppose a same direction as the second opening.

(13) Electronic equipment including a housing that partitions an internal space, a first circuit board that extends in the internal space, a second circuit board including an edge on which a recess portion is provided, and a mounting assembly attached to the first circuit board and configured to electrically connect the second circuit board to the first circuit board, in which the mounting assembly includes a guide portion extending along a first direction intersecting with the first circuit board and including a groove guiding the edge, a projection portion provided in the groove and fitted into the recess portion, and an elastic deformation portion that retracts the projection portion from the groove by the edge elastically deforming against the projection portion in a process where the edge is guided in the groove.

(14) The electronic equipment according to (13), in which in the first direction, an orientation from the first circuit board toward the projection portion is one side in a first direction, and an orientation from the projection portion toward the first circuit board is another side in a first direction, the recess portion includes a first inclined portion inclined on one side in the first direction of the one side in the first direction and the other side in the first direction, the projection portion includes a second inclined portion inclined on the other side in the first direction of the one side in the first direction and the other side in the first direction, the first inclined portion is inclined to be closer to the edge as a position is on the one side in the first direction, and the second inclined portion is inclined to be farther from the elastic deformation portion as a position is on the one side in the first direction.

(15) The electronic equipment according to (13) or (14), in which a through hole is defined in the second circuit board.

(16) The electronic equipment according to (15), in which the second circuit board includes an electronic component mounted at a position spaced away from the through hole.

The refrigerant circulation devices and the electronic equipment according to example embodiments of the present disclosure have industrial applicability.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A refrigerant circulation device comprising:
a first housing including a first opening;
a protrusion protruding from the first housing; and
a pump that is movable in a first direction in an internal space of the first housing through the first opening and is mounted at a mounting position that is a position of one side in the first direction relative to the first opening in the internal space; wherein
the pump includes a first stopper that is movable between a first position that does not overlap with the protrusion in one side of the first direction and a second position that overlaps with the protrusion in one side of the first direction and is on one side in the first direction relative to the protrusion.

2. The refrigerant circulation device according to claim 1, wherein the first stopper is movable to contact with the protrusion while in the second position.

3. The refrigerant circulation device according to claim 1, wherein
the pump further includes:
a second housing including a panel on another side in the first direction; and
a lever supported on the panel rotatably about a shaft along a second direction intersecting the first direction; and
the first stopper is provided around the shaft in the lever.

4. The refrigerant circulation device according to claim 3, wherein
the lever further includes a second stopper movable between a third position not overlapping with the protrusion in the first direction and a fourth position overlapping with the protrusion in the first direction and on the another side in the first direction relative to the protrusion;
the second stopper:
is positioned in the fourth position when the first stopper is in the first position;
is positioned in the third position when the first stopper is in the second position; and
is movable to contact with the protrusion on the another side in the first direction relative to the protrusion when the pump is in the mounting position and in the fourth position.

5. The refrigerant circulation device according to claim 4, wherein the pump further includes a first fixing tool to fix the lever to the second panel when the second stopper is at the third position.

6. The refrigerant circulation device according to claim 5, further comprising a second fixing tool to fix the panel of the pump to the first housing.

7. The refrigerant circulation device according to claim 3, wherein
the first housing includes:
a wall partitioning the internal space; and
a pair of guide rails provided on the wall to guide the second housing in the first direction.

8. The refrigerant circulation device according to claim 7, wherein
the pair of guide rails oppose each other in a third direction intersecting with the first direction; and
an interval in the third direction between the pair of guide rails is widest at a first end and/or a second end in the first direction.

9. The refrigerant circulation device according to claim 1, wherein
the pump includes a suction port and a discharge port; and
the refrigerant circulation device further includes a receiving portion to receive the refrigerant below the suction port and the discharge port.

10. The refrigerant circulation device according to claim 1, wherein the protrusion protrudes inward of the first opening relative to an edge of the first opening in the first housing.

11. A refrigerant circulation device comprising:
a housing including a first opening;
a pump mounted in the housing through the first opening; and
a display assembly that is provided in the housing to display a screen.

12. The refrigerant circulation device according to claim 11, wherein
the refrigerant circulation device is accommodated in a rack;
the rack includes a wall partitioning an internal space opened through a second opening; and
the first opening and the display assembly face a same direction as the second opening.

13. Electronic equipment comprising:
a housing that partitions an internal space;
a first circuit board that expands in the internal space;
a second circuit board including an edge on which a recess portion is provided; and
a mounting assembly attached to the first circuit board and configured to electrically connect the second circuit board to the first circuit board; wherein
the mounting assembly includes:
a guide extending along a first direction intersecting with the first circuit board and including a groove to guide the edge;
a projection portion provided in the groove and fitted into the recess portion; and
an elastic deformation portion to retract the projection portion from the groove by the edge elastically deforming against the projection portion when the edge is guided in the groove.

14. The electronic equipment according to claim 13, wherein
in the first direction, an orientation from the first circuit board toward the projection portion is one side in a first direction, and an orientation from the projection portion toward the first circuit board is another side in a first direction;
the recess portion includes a first inclined portion inclined on one side in the first direction of the one side in the first direction and the another side in the first direction;
the projection portion includes a second inclined portion inclined on the another side in the first direction of the one side in the first direction and the another side in the first direction;
the first inclined portion is inclined to be closer to the edge as a position is on the one side in the first direction; and
the second inclined portion is inclined to be farther from the elastic deformation portion as a position is on the one side in the first direction.

15. The electronic equipment according to claim 13, wherein a through hole is provided in the second circuit board.

16. The electronic equipment according to claim 15, wherein the second circuit board includes an electronic component mounted at a position spaced away from the through hole.
